(19) United States
(12) Patent Application Publication
(10) Pub. No.: US 2026/0327486 A1
(43) Pub. Date: Oct. 22, 2026

(54) QUANTUM DOT, AND ELECTRONIC DEVICE

(71) Applicants: Moon Gyu HAN, Suwon-si (KR); Seung Hwa Hong, Suwon-si (KR); Sohee Jeong, Suwon-si (KR); Daek Won Shin, Suwon-si (KR); Dae-Yong Son, Suwon-si (KR); Taekhoon KIM, Suwon-si (KR); SEON-YEONG KIM, Suwon-si (KR); Meeree Kim, Suwon-si (KR)

(72) Inventors: Moon Gyu HAN, Suwon-si (KR); Seung Hwa Hong, Suwon-si (KR); Sohee Jeong, Suwon-si (KR); Daek Won Shin, Suwon-si (KR); Dae-Yong Son, Suwon-si (KR); Taekhoon KIM, Suwon-si (KR); SEON-YEONG KIM, Suwon-si (KR); Meeree Kim, Suwon-si (KR)

(21) Appl. No.: 19/648,096

(22) Filed: Apr. 15, 2026

(30) Foreign Application Priority Data
Apr. 16, 2025 (KR) 10-2025-0049417

(51) Int. Cl. C09K 11/06; B82Y 20/00; B82Y 40/00; C09K 113/00; H10K 30/60; H10K 30/65; H10K 71/40; H10K 85/30; H10K 101/30

(52) U.S. Cl. CPC C09K 11/06; B82Y 20/00; B82Y 40/00; H10K 30/60; H10K 30/65; H10K 71/40; H10K 85/324; H10K 85/326; C09K 2113/00; C09K 2211/1025; H10K 2101/30

(57) ABSTRACT

A method of preparing a quantum dot includes: preparing a precursor solution of a Group IIIA element including a precursor of a Group IIIA element, a first amine compound, and a phosphine compound, and heating the precursor solution to maintain it at a first temperature; preparing a precursor solution of a Group VA element including a precursor of a Group VA element and a second amine compound; injecting the precursor solution of the Group VA element into the precursor solution of the Group IIIA element maintained at a first temperature to form a mixture and to react them; and rapidly increasing temperature of the mixture to a second temperature that is higher than the first temperature to cause an additional reaction, wherein the obtained quantum dot has an absorption peak wavelength of about 1,100 nm to about 1,600 nm in a visible-infrared absorption spectrum.

### CROSS-REFERENCE TO RELATED APPLICATION

This application claims priority to and the benefit of Korean Patent Application No. 10-2025-0049417 filed with the Korean Intellectual Property Office on Apr. 16, 2025, and all the benefits accruing therefrom under 35 U.S.C. § 119, the content of which in its entirety is herein incorporated by reference.

### BACKGROUND

### 1. Field

A method of preparing a quantum dot, a quantum dot, and an electronic device are disclosed.

### 2. Description of the Related Art

Physical characteristics (e.g., bandgap energies, melting points, etc.), which are known as intrinsic characteristics, of nanoparticles may be controlled, for example, by changing particle sizes of the nanoparticles, unlike bulk materials. For example, semiconductor nanocrystals, also known as quantum dots (QDs), are semiconductor materials with a crystal structure of several nanometers in size. Semiconductor nanocrystals are very small in size, have a large surface area per unit volume and exhibit quantum confinement effects, and may exhibit different physicochemical characteristics from bulk materials. For example, bandgap energies of quantum dots may be tunable depending on sizes and compositions thereof, and the quantum dots may be able to absorb light of different wavelengths or emit light of specific wavelengths. Interest in quantum dots is high as quantum dots may be applied in various fields such as displays, energy, electronics, and bio.

Quantum dots based on cadmium (Cd), lead (Pb), or mercury (Hg) may exhibit enhanced optical properties. However, such elements are toxic heavy metal elements that may pose a serious threat to the environment, and there is a desire for the development of quantum dots that have excellent characteristics of absorbing or emitting light in a specific region and a method for preparing the same, without including such toxic heavy metal elements.

### SUMMARY

An embodiment provides a quantum dot capable of absorbing light of a longer wavelength in the near-infrared region without containing heavy metals harmful to the environment, and a method for preparing the same.

An embodiment provides an electronic device including the quantum dot.

A method for preparing a quantum dot having an absorption peak wavelength of greater than or equal to about 1,100 nanometers (nm) and less than or equal to about 1,600 nm in a visible-infrared (Vis-IR) absorption spectrum according to an embodiment, includes
preparing a precursor solution of a Group IIIA element including a precursor of a Group IIIA element, a first amine compound, and a phosphine compound, and heating the precursor solution to maintain the precursor solution at a first temperature;
preparing a precursor solution of a Group VA element including a precursor of a Group VA element and a second amine compound;
injecting the precursor solution of the Group VA element into the precursor solution of the Group IIIA element maintained at the first temperature to form a mixture and to react the precursor solution of the Group VA element and the precursor solution of the Group IIIA element; and
increasing temperature of the mixture to a second temperature higher than the first temperature to cause an additional reaction.

The precursor of the Group IIIA element may include a halide of the Group IIIA element, a sulfide of the Group IIIA element, an amine compound of the Group IIIA element, or a combination thereof; and the precursor of the Group VA element may include a halide of the Group VA element, a sulfide of the Group VA element, an amine compound of the Group VA element, or a combination thereof.

The first amine compound and the second amine compound may be the same as or different from each other, and each independently may include RNH₂, R₂NH, or a combination thereof, wherein, each R independently may represent a C5 to C40 substituted or unsubstituted aliphatic hydrocarbon group, a C6 to C40 substituted or unsubstituted aromatic hydrocarbon group, or a combination thereof.

The phosphine compound may include R₃PO, R₂HPO, RH₂PO, R₃P, R₂PH, RPH₂, RPO(OH)₂, RHPOOH, RHPOOH, R₂POOH, or a combination thereof, wherein, each R independently may represent a C5 to C40 substituted or unsubstituted aliphatic hydrocarbon group, a C6 to C40 substituted or unsubstituted aromatic hydrocarbon group, or a combination thereof.

The first temperature may be greater than or equal to about 220 °C and less than or equal to about 270 °C, and the second temperature may be greater than about 270 °C and less than or equal to about 380 °C.

A temperature increase from the first temperature to the second temperature may occur within 5 minutes.

The method for preparing the quantum dot may further include, after the additional reaction at the second temperature, replacing the first amine compound, the second amine compound, the phosphine compound, or a combination thereof on a surface of the quantum dot obtained therefrom with an aliphatic hydrocarbon compound substituted with a hydroxyl group (—OH) and a thiol group (—SH), a metal halide, or a combination thereof.

The aliphatic hydrocarbon compound substituted with the hydroxyl group (—OH) and the thiol group (—SH) may include 1-hydroxy-2-mercaptoethane (ME), 1,2-dihydroxy-3-mercaptopropane (MPD), or a combination thereof, and the metal halide may include InBr, InI, InCl, ZnCl₂, ZnI₂, ZnBr₂, or a combination thereof.

In an embodiment, a quantum dot includes a Group IIIA element and a Group VA element, wherein the quantum dot does not include mercury, cadmium, lead, or a combination thereof, and has an absorption peak wavelength of greater than or equal to about 1,100 nm and less than or equal to about 1,600 nm in a visible-infrared (Vis-IR) absorption spectrum.

The Group IIIA element may include indium (In), aluminum (Al), gallium (Ga), or a combination thereof, and the Group VA element may include arsenic (As), antimony (Sb), bismuth (Bi), or a combination thereof.

The quantum dot may include indium (In) and arsenic (As).

The quantum dot may include an amine compound, a phosphine compound, or a combination thereof on a surface thereof.

The quantum dot may include a ligand derived from an aliphatic hydrocarbon compound substituted with a hydroxyl group (—OH) and a thiol group (—SH), a metal halide, or a combination thereof on a surface thereof.

The ligand may be derived from a linear or branched aliphatic hydrocarbon compound having 2 to 30 carbon atoms substituted with a, e.g., one or more, hydroxyl group and a, e.g., one or more, thiol group.

The metal halide may include a halide of a Group IIIA metal, a halide of a Group IIA metal, or a combination thereof.

The quantum dot may have an average particle size of greater than or equal to about 2.5 nanometers and less than or equal to about 20 nanometers, or have a molar ratio of the Group IIIA element to the Group VA element of about 1:1 to about 2:1.

According to an embodiment, an electronic device includes a first electrode and a second electrode spaced apart from each other; and a semiconductor layer between the first electrode and the second electrode, wherein the semiconductor layer includes quantum dot, and wherein the quantum dot includes a Group IIIA element and a Group VA element of the periodic table of elements, does not include mercury, cadmium, lead, or a combination thereof, and has an absorption peak wavelength of greater than or equal to about 1,100 nm and less than or equal to about 1,600 nm in a visible-infrared (Vis-IR) absorption spectrum.

The quantum dot included in the semiconductor layer includes indium (In) and arsenic (As.

The first electrode and the second electrode may have main surfaces facing each other, and the semiconductor layer may be interposed between the first electrode and the second electrode.

The electronic device may include a charge auxiliary layer between the semiconductor layer and the first electrode, between the semiconductor layer and the second electrode, or both.

The electronic device may further include a third electrode facing the semiconductor layer; and an insulating layer between the semiconductor layer and the third electrode.

A method for preparing a quantum dot according to an embodiment is a method capable of stably preparing a quantum dot having a uniform size and shape, high reproducibility, and an absorption peak wavelength of greater than or equal to about 1,100 nm and less than or equal to about 1,600 nm, without including toxic heavy metal elements such as cadmium, lead, and mercury. By replacing the ligand on the surface of the quantum dot to improve surface passivation, charge mobility may be increased and a deeper Highest Occupied Molecular Orbital (HOMO) energy may be achieved. The quantum dot according to an embodiment may be advantageously applied to semiconductor thin films in devices such as photodiodes, photodetectors, and field effect transistors.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1 is a schematic view of an electronic device according to an embodiment.

FIG. 2 is a schematic view of an electronic device according to an embodiment.

FIG. 3 is a cross-sectional schematic view of an electronic device according to an embodiment.

FIG. 4 is a cross-sectional schematic view of an electronic device according to an embodiment.

FIG. 5 is a TEM image of the quantum dot prepared in Example 1.

FIG. 6 is a graph of absorbance (arbitrary units) versus wavelength (nm) showing Vis-IR absorption spectra of the quantum dots prepared in Reference Example 1 and Example 1.

FIG. 7 is a TEM image of the quantum dot prepared in Example 2.

FIG. 8 is a graph of absorbance (arbitrary units) versus wavelength (nm) showing Vis-IR absorption spectra of the quantum dots prepared in Reference Example 2 and Example 2.

FIG. 9 is a graph of absorbance (arbitrary units) versus wavelength (nm) showing a Vis-IR absorption spectrum of the quantum dot prepared in Comparative Example 1.

FIG. 10 is a TEM image of the quantum dot prepared in Comparative Example 1.

FIG. 11 is a graph of absorbance (arbitrary units) versus wavelength (nm) showing a Vis-IR absorption spectrum graph of the quantum dot prepared in Example 3.

FIG. 12 is a graph of photoluminescence (PL) intensity (count) versus wavelength (nm) showing the emission spectra of the quantum dots prepared in Examples 3 to 5.

FIG. 13 is a graph of photoemission^{1/3} (arbitrary units (a.u.)) versus energy (electronvolts (eV)) showing the intensity of photoelectron generation according to the energy applied to each thin film of the quantum dots prepared in Examples 3 and 5, respectively.

FIG. 14 is a graph of drain current (Ids) (amperes (A)) versus gate voltage (Vg) (volts (V)) of a FET device including the quantum dot according to Example 3 and the quantum dot according to Example 5 in a semiconductor layer (source-drain current versus gate voltage: IDS-VG).

FIG. 15 is a graph of current density (amperes per square centimeter (A/cm²)) versus voltage (V) showing the results of wavelength-dependent external quantum efficiency (EQE) measurements while increasing the voltage on a photodiode element including the quantum dot according to Example 5 in a semiconductor layer.

FIG. 16 is a graph of EQE (percent (%)) versus wavelength (nm) showing the wavelength-dependent EQE measurement results of a photodiode element including the quantum dot according to Example 5.

FIG. 17 is a graph of EQE value (percent (%)) versus voltage (V) of a photodiode element including the quantum dot according to Example 5.

FIG. 18 is a graph of current density (A/cm²) versus voltage (V) of a FET device including, in a semiconductor layer, an InAs quantum dot surface-modified with MPD in the same manner as the quantum dot of Example 5, but having a smaller particle size and shorter wavelength absorption peak than the quantum dot of Example 5 (source-drain current versus gate voltage: IDS-VG).

FIG. 19 is a of wavelength-dependent EQE (%) versus wavelength (nm) when a bias voltage of −1 V is applied to a photodiode element including the quantum dot of FIG. 18 in a semiconductor layer, and when a bias voltage of −2 V is applied to a photodiode element with a p-type InAs layer added between the semiconductor layer and the hole transport layer of the element.

FIG. 20 is a graph of detectivity (Jones (centimeters-hertz^{1/2} per watt (cm·Hz^{1/2}·W⁻¹))) versus wavelength (nm) showing the wavelength-dependent detectivity results of a photodiode element including the quantum dot of FIG. 18 in a semiconductor layer.

### DETAILED DESCRIPTION

Advantages and characteristics of this disclosure, and a method for achieving the same, will become evident referring to the following embodiments together with the drawings attached hereto. However, the embodiments should not be construed as being limited to the embodiments set forth herein. If not defined otherwise, all terms (including technical and scientific terms) in the specification may be defined as commonly understood by one skilled in the art. The terms defined in a generally-used dictionary may not be interpreted ideally or exaggeratedly unless clearly defined.

In addition, unless explicitly described to the contrary, the word “comprise,” and variations such as “comprises” or “comprising,” will be understood to imply the inclusion of stated elements but not the exclusion of any other elements. Further, the singular includes the plural unless mentioned otherwise. Thus, reference to “an” element in a claim followed by reference to “the” element is inclusive of one element and a plurality of the elements.

As used herein, the term “and/or” includes any and all combinations of one or more of the associated listed elements. An expression like “at least one” when preceding a list of elements, modifies the entire list of elements, not individual elements of the list.

The terms first, second, tertiary, etc. may be used to describe various elements, components, regions, layers, etc., but these elements, components, regions, layers, etc. should not be limited by these terms. These terms are used to distinguish one element, component, domain, layer, etc. from another element, component, domain, layer, etc. Accordingly, the first element, component, region, layer, etc. described below may be referred to as a second element, component, region, layer, etc. without departing from the disclosure of the present embodiment.

The terminology used in this specification is for the purpose of describing particular implementations and is not intended to be limiting. Unless specifically stated otherwise, “or” may also mean “and/or”.

In the drawings, the thickness of layers, films, panels, regions, etc., are exaggerated for clarity. Like reference numerals designate like elements throughout the specification.

In this specification, when a first element, such as a layer, film, region, or plate, is said to be “on” a second element, this includes not only cases where it is “directly on” another portion, but also cases where there is another portion therebetween. Conversely, when a portion is “directly on” another portion, it means that there are no other portions therebetween.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, as used herein, when a definition is not otherwise provided, “substituted” refers to replacement of hydrogen of a compound, a group, or moiety by a substituent selected from a C1 to C30 alkyl group, a C2 to C30 alkenyl group, a C2 to C30 alkynyl group, a C2 to C30 epoxy group, a C2 to C30 alkenyl group, a C2 to C30 alkylester group, a C3 to C30 alkenylester group (e.g., an acrylate group or a methacrylate group), a C6 to C30 aryl group, a C7 to C30 alkylaryl group, a C1 to C30 alkoxy group, a C1 to C30 heteroalkyl group, a C3 to C30 heteroalkylaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a thiocyanate group (—SCN), a cyano group (—CN), an amino group (—NRR′ wherein R and R′ are each independently hydrogen or a C1 to C6 alkyl group), an azido group (—N₃), an amidino group (—C(═NH)NH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation), a sulfonic acid group (—SO₃H) or a salt thereof (~SO₃M, wherein M is an organic or inorganic cation), a phosphoric acid group (—PO₃H₂) or a salt thereof (~PO₃MH or —PO₃M₂, wherein M is an organic or inorganic cation), or a combination thereof.

Additionally, as used herein, when a definition is not otherwise provided, “hetero” means including 1 to 3 heteroatoms selected from N, O, S, Si, and P.

As used herein, when a definition is not otherwise provided, an “alkyl group” is, for example, a monovalent linear or branched or cyclic saturated aliphatic hydrocarbon group which may optionally include one or more substituents.

Additionally, as used herein, when a definition is not otherwise provided, “aliphatic” means a C1 to C30 linear or branched or cyclic non-aromatic saturated or unsaturated hydrocarbon group (e.g., C1 to C30 alkyl, C2 to C30 alkenyl, C2 to C30 alkynyl), and “aromatic” means a C6 to C30 aryl group or a C2 to C30 heteroaryl group.

Infrared (IR) absorbing materials that absorb light in a near infrared region may be applied in the field of IR imaging, such as night vision, tracking, remote temperature sensing, short-ranged wireless communications, spectroscopy, solar cells, bio-imaging, augmented/virtual reality (AR/VR), LIDAR (Light Detection and Ranging), or ToF (Time of Flight) sensors. For example, with advancement of technologies such as autonomous driving, drones, and robots, sensors that recognize light beyond the visible region that humans cannot perceive, are emerging as important components in various machines, automobiles, and robots. Quantum dots with silicon, e.g., may enable camera applications detecting both short wave infrared wavelengths (SWIR) and mid wave infrared wavelengths allowing enhanced perception of surroundings capabilities.

However, silicon may have some limited effectiveness at, e.g., some infrared wavelengths thereby potentially limiting its applications. Silicon may have weak absorption in the IR region and a quantum efficiency (QE) of less than 20%, limiting its use thereof in the far-IR region. For example, in the short wavelength IR (SWIR) region, that is, the wavelength range of approximately 1 micrometer (μm) or greater, which may be less affected by external light, less scattering by water or small particles, and has excellent eye safety, the QE (quantum efficiency, e.g., effectiveness of conversion to electrical charge) of silicon may be close to 0%, requiring replacement with other materials.

InGaAs (indium-gallium-arsenide) is a material that can replace silicon as a sensor material in the SWIR region, but may be very expensive, which may limit commercialization thereof in various fields. To avoid the high price and preparing process issues of InGaAs, PbS (lead-sulfur) or PbSe (lead-selenium) quantum dots (QDs) may be used. However, due to, for example, environmental issues related to lead (Pb), there is a desire to develop IR absorbing materials that can replace lead.

Except for indium phosphide (InP), there may be many challenges in the synthesis of quantum dot based on indium and Group V elements that can absorb long-wavelength light, such as infrared or near-infrared. For example, there have been attempts to prepare indium antimonide (InSb)-based quantum dot using indium amide and antimony amide precursors dissolved in trioctylphosphine or oleylamine. However, such preparing method may have problems with reproducibility due to, for example, the volatility of the antimony precursor, and for example, the size distribution of the prepared quantum dot may be inferior, an extensive size selection process may be involved, and the reaction and preparation yields may also be inferior. In a co-reduction method, indium chloride dissolved in trioctylphosphine and antimony silylamide dissolved in toluene may be used as precursors to carry out the reaction in the presence of superhydride. However, such method may also have problems with reproducibility, inferior size distribution of the prepared quantum dot, low preparation yield, and generation of a large amount of insoluble byproduct. When indium chloride and a silylamide of a Group V element, such as antimony (Sb), are reacted as a precursor in an organic medium in the presence of a superhydride, but when the organic medium does not include trioctylphosphine, the prepared indium-based quantum dot may be more likely to aggregate and may exhibit higher resistance. In the case of InSb quantum dot prepared by such a method, desirable characteristics of the InSb quantum dot may be significantly lower than those of existing PbS quantum dot, and much improvement is desired for application in various fields as SWIR materials.

Research on InAs (indium arsenide) quantum dot has been actively conducted. For the development of InAs quantum dot, a method for preparing quantum dot may use inexpensive precursors that may be applied to, e.g., used in, mass production, may not involve an additional reducing agent using a disproportionation reaction, or a combination thereof. However, InAs quantum dot prepared using such preparing methods may have a problem of having an anisotropic shape as a particle size thereof may exceed a certain size, and exhibit light absorption characteristics in the near infrared (NIR) to short wavelength infrared (SWIR) region. It is possible to consider reacting the precursors of quantum dot at a higher temperature to further increase the size of the quantum dot so that the quantum dot can absorb longer wavelength infrared light, but, as described herein, there may be a problem that the shape of the prepared quantum dot becomes anisotropic. The size of the prepared quantum dot may be non-uniform and reproducibility may be low, and a decrease in yield and the generation of byproducts during mass production of quantum dot may be caused. Such affects may be more significant as the particle size of quantum dot increases and the quantum dots absorb longer wavelengths. A method for preparing quantum dot that has high uniformity in shape and size, which has excellent reproducibility, and exhibits light absorption characteristics in the infrared region of longer wavelengths is desired to provide high-performance/multipurpose optical devices.

The present inventors have developed a novel preparing method for a quantum dot including a Group IIIA element and a Group VA element, not including hazardous metals such as mercury, cadmium, and lead, and having a longer-wavelength absorption peak wavelength in a visible-infrared (Vis-IR) absorption spectrum, which includes: preparing precursor solutions each including precursors of the quantum dot, mixing and reacting the precursor solutions at a first temperature, and, after the reaction, increasing, for example, rapidly increasing a temperature of the reactants from the first temperature to a second temperature that is higher than the first temperature to cause an additional reaction. The disclosed method for preparing the quantum dot solves the problem of quantum dot prepared using existing preparing methods being prepared in an anisotropic shape and having low size uniformity, and is a method for preparing a quantum dot with a uniform particle size and uniform equidirectional shape and having an absorption peak wavelength in the infrared region with high reproducibility. The method for preparing a quantum dot according to an embodiment is a method for preparing a quantum dot that has a longer absorption peak wavelength in near-infrared region, for example, of greater than or equal to about 1,100 nm and less than or equal to about 1,600 nm, has a uniform size and shape, does not contain hazardous metals such as mercury, cadmium, or lead, and contains a Group IIIA element and a Group IVA element.

A method for preparing a quantum dot having an absorption peak wavelength of greater than or equal to about 1,100 nm and less than or equal to about 1,600 nm in a visible-infrared absorption spectrum according to an embodiment includes: preparing a precursor solution of a Group IIIA element including a precursor of a Group IIIA element, a first amine compound, and a phosphine compound, and heating the precursor solution to maintain the precursor solution at a first temperature; preparing a precursor solution of a Group VA element including a precursor of a Group VA element and a second amine compound; injecting the precursor solution of the Group VA element into the precursor solution of the Group IIIA element maintained at a first temperature to form a mixture and to react the precursor solution of the Group VA element and the precursor solution of the Group IIIA element; and increasing, for example, rapidly increasing temperature of the mixture to a second temperature that is higher than the first temperature to cause an additional reaction

The Group IIIA element of the quantum dot may include indium (In), aluminum (Al), gallium (Ga), or a combination thereof, for example, may include indium (In), gallium (Ga), or a combination thereof, or for example, may include indium (In).

The Group VA element of the quantum dot may include arsenic (As), antimony (Sb), bismuth (Bi), or a combination thereof, for example, may include arsenic (As), antimony (Sb), or a combination thereof, or for example, may include arsenic (As).

For example, the Group IIIA element may include indium (In), the Group VA element may include arsenic (As), and optionally, the Group IIIA element may further include gallium (Ga), and the Group VA element may further include antimony (Sb).

The precursor of the Group IIIA element and the precursor of the Group VA element may include a halide, a sulfide, an amine-based compound of the Group IIIA element and the Group VA element, or a combination thereof, respectively. The precursor of the Group IIIA element comprises a halide of, e.g., comprising, the Group IIIA element, a sulfide of, e.g., comprising, the Group IIIA element, an amine compound of, e.g., comprising, the Group IIIA element, or a combination thereof; and the precursor of the Group VA element comprises a halide of, e.g., comprising, the Group VA element, a sulfide of, e.g., comprising, the Group VA element, an amine compound of, e.g., comprising, the Group VA element, or a combination thereof.

For example, the precursor of the Group IIIA element may include a halide of the Group IIIA element, for example, a fluoride of the Group IIIA element, a chloride of the Group IIIA element, a bromide of the Group IIIA element, or an iodide of the Group IIIA element. For example, the precursor of the Group IIIA element may be indium fluoride, indium chloride, indium bromide, indium iodide, aluminum fluoride, aluminum chloride, aluminum bromide, aluminum iodide, gallium fluoride, gallium chloride, gallium bromide, or gallium iodide, or may include, for example, indium fluoride, indium chloride, indium bromide, or indium iodide, or, for example, the precursor of the Group IIIA element may include indium chloride.

For example, the precursor of the Group VA element may include a halide or an amine-based compound including the Group VA element, for example, the precursor of the Group VA element may include a halide of arsenic (As), antimony (Sb), bismuth (Bi), or a combination thereof, or an amine-based compound of arsenic (As), antimony (Sb), bismuth (Bi), or a combination thereof. For example, the precursor of the Group VA element may include a halide of arsenic (As) or antimony (Sb), or an amine-based compound of arsenic (As) or antimony (Sb). In an embodiment, the precursor of the Group VA element may include, for example, dimethylaminoarsine, tris(dimethylamino)arsine, arsine chloride (AsCl₃), arsine bromide (AsBr₃), arsine iodide (AsI₃), or a combination thereof.

The first amine compound and the second amine compound may be the same or different, and may each independently have at least one C1 to C40 aliphatic hydrocarbon group, at least one C6 to C40 aromatic hydrocarbon group, or a combination thereof. For example, the first amine compound and the second amine compound may each independently include RNH₂, R₂NH, or a combination thereof (wherein, each R may independently represent a C5 to C40 substituted or unsubstituted aliphatic hydrocarbon group, a C6 to C40 substituted or unsubstituted aromatic hydrocarbon group, or a combination thereof). For example, the first amine compound and the second amine compound may each independently include an amine having a C6 to C40 alkenyl group, an amine having a C6 to C40 alkyl group, or a combination thereof, and the first amine compound and the second amine compound may not include a tertiary amine. For example, the first amine compound and the second amine compound may each independently include oleylamine, butylamine, octylamine, dioctylamine, dodecylamine, hexadecylamine, hexylamine, propylamine, aniline, benzylamine, octadecylamine, or a combination thereof.

The phosphine compound may include a compound having at least one (two or three) C1 to C40 aliphatic hydrocarbon group, at least one (two or three) C6 to C40 aromatic hydrocarbon group, or a combination thereof, linked to a phosphorus atom. For example, the phosphine compound may include R₃PO, R₂HPO, RH₂PO, R₃P, R₂PH, RPH₂, RPO(OH)₂, RHPOOH, RHPOOH, R₂POOH, or a combination thereof (wherein, each R may independently represent a C5 to C40 substituted or unsubstituted aliphatic hydrocarbon group, a C6 to C40 substituted or unsubstituted aromatic hydrocarbon group, or a combination thereof). For example, the phosphine compound may include an alkyl or aryl phosphine (R₃P or R₂PH), or may include, for example, trioctylphosphine (TOP), diphenylphosphine, or a combination thereof.

In an embodiment, the reaction may be performed in the absence of a phosphine compound (e.g., trioctylphosphine). Without wishing to be bound by any theory, it is believed that the use of TOP may result in the production of elongated particles, and may provide a more uniform population of particles, for example, by not using trioctylphosphine during the reaction or prior to particle formation.

In the process of preparing the precursor solution of the Group IIIA element, the process may further include degassing with nitrogen gas after mixing the precursor of the Group IIIA element and the first amine compound and before mixing the phosphine compound. By removing oxygen in the solution through the degassing process, oxidation of the precursor material and the quantum dot prepared therefrom may be suppressed, and the reactants and products may be maintained more stably.

After the degassing, the precursor solution of the Group IIIA element is prepared by mixing a phosphine compound, and the solution is heated to rapidly increase a temperature thereof and maintain the temperature thereof at the first temperature. The first temperature may be greater than or equal to about 220 °C and less than or equal to about 270 °C, for example, greater than or equal to about 230 °C and less than or equal to about 270 °C, greater than or equal to about 240 °C and less than or equal to about 270 °C, greater than or equal to about 250 °C and less than or equal to about 270 °C, or greater than or equal to about 260 °C and less than or equal to about 270 °C. The first temperature is a temperature at which the precursor solution of the Group IIIA element and the precursor solution of the Group VA element are mixed and reacted for the first time, and is a temperature lower than the second temperature. At the first temperature, the precursor of the Group IIIA element and the precursor of the Group VA element in the mixture may undergo a first reaction to form a first quantum dot. The first quantum dot refers to a quantum dot having an absorption peak wavelength of less than about 1,100 nm in the absorption spectrum of the Vis-IR region, which has a smaller average particle diameter than the quantum dot prepared by the method according to an embodiment and having an absorption peak wavelength of greater than or equal to about 1,100 nm and less than or equal to about 1,600 nm in the absorption spectrum of the Vis-IR region. A method for preparing a quantum dot according to an embodiment is a method in which a precursor solution of a Group VA element is injected into a precursor solution of a Group IIIA element while maintaining the temperature of the precursor solution of a Group IIIA element at the first temperature to form a mixture, and then the precursors in the mixture undergo a primary reaction at the first temperature to form a first quantum dot having a shorter absorption peak wavelength than the quantum dot to be finally prepared, and then the temperature of the mixture is increased to a second temperature that is higher than the first temperature to perform an additional reaction, and the first quantum dot may be grown to form a final quantum dot having an absorption peak wavelength of greater than or equal to about 1,100 nm and less than or equal to about 1,600 nm. The quantum dot prepared in the disclosed manner may be prepared into a quantum dot having an overall uniform size and shape and having a longer-wavelength absorption peak wavelength than the first quantum dot, by increasing, for example, rapidly increasing the temperature to a second temperature for additional reaction after preparing a first quantum dot, and the precursors of the quantum dot in the mixture may immediately react and grow on the surface of the first quantum dot. The time to prepare the first quantum dot by reacting at the first temperature may be approximately 10 minutes, and even if the reaction time elapses further, for example, even if the reaction is maintained for approximately 30 minutes, the particle size or shape of the first quantum dot prepared therefrom does not significantly increase or change. The first temperature may be a temperature at which quantum dot having an absorption peak wavelength of a Vis-IR absorption spectrum of less than about 1,100 nm may be stably formed.

The second temperature at which the first quantum dot further react may be a temperature higher than the first temperature, and may be, for example, greater than about 270 °C and less than or equal to about 380 °C, for example, greater than or equal to about 280 °C and less than or equal to about 380 °C, greater than or equal to about 290 °C and less than or equal to about 380 °C, greater than or equal to about 300 °C and less than or equal to about 380 °C, greater than or equal to about 310 °C and less than or equal to about 380 °C, greater than or equal to about 320 °C and less than or equal to about 380 °C, greater than or equal to about 330 °C and less than or equal to about 380 °C, greater than or equal to about 340 °C and less than or equal to about 380 °C, greater than or equal to about 350 °C and less than or equal to about 380 °C, greater than or equal to about 350 °C and less than or equal to about 370 °C, greater than or equal to about 360 °C and less than or equal to about 380 °C, greater than or equal to about 360 °C and less than or equal to about 370 °C, or greater than or equal to about 370 °C and less than or equal to about 380 °C. The higher the reaction temperature, the larger the quantum dot size may be formed, and a quantum dot having an absorption peak wavelength in the longer-wavelength infrared region may be prepared. The second temperature may be appropriately selected and controlled within the disclosed temperature range to prepare a quantum dot having a desired absorption peak wavelength.

As described herein, the method for preparing a quantum dot according to an embodiment includes increasing, for example, rapidly increasing the temperature of the mixed solution from the first temperature to the second temperature. The time for increasing the temperature from the first temperature to the second temperature may be within about 5 minutes, for example, within about 4 minutes, within about 3 minutes, within about 2 minutes, or within about 1 minute.

Without wishing to be bound by any theory, it is believed that a method for preparing a quantum dot involving mixing precursors of quantum dot at a high reaction temperature and maintaining the reaction may prepare a quantum dot having a longer-wavelength absorption peak wavelength. Without wishing to be bound by any theory, it is believed that since the precursors react rapidly at the high reaction temperature, the particle size of the prepared quantum dots is non-uniform, an anisotropic quantum dot is prepared, or a combination thereof. Without wishing to be bound by any theory, it is believed that the method for preparing the quantum dot according to an embodiment stably prepares a first quantum dot having a uniform size and shape with a shorter absorption peak wavelength under milder conditions by mixing and reacting precursors at a first temperature lower than the final reaction temperature, i.e., the second temperature, and by increase, for example, rapid increase of the temperature of the reactants including the prepared first quantum dot from the first temperature to the second temperature, which is the final reaction temperature, the precursors additionally react and grow on the surface of the uniformly formed first quantum dot, and a quantum dot having a larger average particle size than the first quantum dot and an overall uniform size and isotropic shape may be reproducibly prepared. The quantum dot prepared by the preparing method according to an embodiment may have an absorption peak wavelength of greater than or equal to about 1,100 nm and less than or equal to about 1,600 nm in the Vis-IR absorption spectrum.

In an embodiment, the precursor solution of the Group VA element may be preheated to a certain temperature, for example, about 50 °C, before being injected into the precursor solution of the Group IIIA element.

The amounts of the precursor of the Group IIIA element and the precursor of the Group VA element may be adjusted to an appropriate range taking into consideration the bandgap energy of the quantum dot prepared therefrom, and the range of the maximum absorption peak wavelength of the quantum dot, and for example, the amounts of the precursor solutions of the elements may be included in an amount such that a molar ratio of the Group VA element to the Group IIIA element in the quantum dot is in a range of greater than or equal to about 0.5:1.0 and less than or equal to about 1.0:1.0, for example, a molar ratio of about 1:1.

The reaction at the second temperature may be completed within a certain period of time, for example, within about 1 hour. By reacting at the second temperature for about 1 hour, a quantum dot including a Group IIIA element and a Group VA element and having an absorption peak wavelength of greater than or equal to about 1,100 nm and less than or equal to about 1,600 nm may be prepared. After the reaction is completed, the temperature of the reactant is cooled to room temperature, for example, to a temperature of about 25 °C, and then, by adding a solvent included in the reactant, for example, a nonsolvent that is not miscible with the first amine compound, the second amine compound, the phosphine compound, or a combination thereof, the formed quantum dot may be separated by causing the quantum dot(s) to be precipitated. For example, the method may include separating the precipitated quantum dot by a method such as centrifugation after addition of the nonsolvent.

The nonsolvent may include, for example, a C1 to C10 alcohol, a ketone, a nitrile, or a combination thereof. For example, the nonsolvent may include, hexane or n-butanol.

The separated quantum dot may be washed by resuspending the separated quantum dot in, for example, hexane or n-butanol, and separated through additional centrifugation.

As can be seen from Examples described herein, the quantum dot prepared as described herein has an absorption peak wavelength of greater than or equal to about 1,100 nm and less than or equal to about 1,600 nm in the visible-infrared (Vis-IR) absorption spectrum, and, as can be confirmed from a transmission electron microscope (TEM) image, has an overall uniform size and isotropic shape. Such a quantum dot may be advantageously applied to the photoactive layers of various electronic devices that absorb wavelengths in the infrared range and convert the wavelengths into electrical signals.

The quantum dot may include a first amine compound, a second amine compound, a phosphine compound, or a combination thereof included in each precursor solution on a surface thereof.

After redispersing the prepared quantum dot in an appropriate solvent, a ligand substitution reaction may be further performed to replace the first amine compound, the second amine compound, the phosphine compound, or a combination thereof present on the surface of the quantum dot with another compound. For example, the ligand substitution reaction may include replacing the first amine compound, the second amine compound, the phosphine compound, or a combination thereof present on the surface of the quantum dot with an aliphatic hydrocarbon compound substituted with a hydroxy group and a thiol group, a metal halide, or a combination thereof.

The ligand substitution reaction may include contacting the separated quantum dot with a solution including a compound to be substituted, for example, an aliphatic hydrocarbon compound substituted with a hydroxyl group and a thiol group, a metal halide, or a combination thereof, for example, a solution including a polar organic solvent. For example, when the prepared quantum dot is dispersed in a suitable organic solvent, for example, a non-polar organic solvent, and the dispersion is added to a solution including the compound to be substituted, phase separation of the polar organic solvent and the non-polar organic solvent may occur. The quantum dot may move to a polar organic solvent in which the compound to be substituted is dissolved by phase transfer, and the first amine compound, the second amine compound, the phosphine compound, or a combination thereof present on the surface of the quantum dot may be separated from the quantum dot. The surface of the quantum dot moved into the polar organic solvent may be modified by the hydrocarbon compound substituted with the hydroxyl group and the thiol group, the metal halide, or the combination thereof dissolved in the polar organic solvent, and the ligand substitution reaction may be completed. The ligand-substituted quantum dot may be separated by separating the polar organic solvent layer through phase separation of the polar organic solvent and the non-polar organic solvent, or by centrifugation. The separated quantum dot may be obtained as a final product through washing and resuspension processes using additional solvents.

The polar organic solvent and non-polar organic solvent used in the ligand substitution reaction may be any polar organic solvent or non-polar organic solvent suitable for use for phase separation reactions. For example, the nonpolar organic solvent may be an aliphatic hydrocarbon compound having 1 to 30 carbon atoms, such as hexane, octane, or cyclohexane, and the polar organic solvent may be, for example, DMF (N,N-dimethylformamide) or DMSO (dimethyl sulfoxide).

When performing the ligand substitution reaction, an amount of the ligand present on the surface of the quantum dot may be adjusted by controlling the amount of the ligand compound in a polar organic solvent including the substituted ligand compound. For example, the amount of the ligand substituted on the surface of the quantum dot by the ligand substitution reaction may be substituted in an amount that allows the substituted ligand to uniformly passivate the entire surface of the quantum dot. The amount of such ligands may be adjusted, for example, in a range of about 10 weight percent (wt %) to about 80 wt %, based on the ligand density of the quantum dot. For example, the amount of the ligand may be about 10 wt % to about 75 wt %, for example, about 15 wt % to about 75 wt %, about 15 wt % to about 70 wt %, about 20 wt % to about 75 wt %, about 20 wt % to about 70 wt %, about 20 wt % to about 65 wt %, about 20 wt % to about 60 wt %, about 25 wt % to about 75 wt %, about 25 wt % to about 70 wt %, about 25 wt % to about 65 wt %, about 30 wt % to about 75 wt %, about 30 wt % to about 70 wt %, about 30 wt % to about 65 wt %, about 30 wt % to about 60 wt %, about 35 wt % to about 75 wt %, about 35 wt % to about 70 wt %, about 35 wt % to about 65 wt %, about 40 wt % to about 75 wt %, about 40 wt % to about 70 wt %, about 40 wt % to about 65 wt %, or about 40 wt % to about 60 wt %, based on the ligand density.

When the substituted ligand is derived from the aliphatic hydrocarbon compound substituted with the hydroxyl group and thiol group, the metal halide, or the combination thereof, the total amount of the ligand derived from the aliphatic hydrocarbon compound substituted with the hydroxyl group and thiol group, the metal halide, or the combination thereof may be within the range described herein. For example, when the ligand substitution reaction is performed only with the aliphatic hydrocarbon compound substituted with the hydroxyl group and the thiol group, the aliphatic hydrocarbon compound substituted with the hydroxyl group and the thiol group may be present on the surface of the quantum dot in a range of about 10 wt % to about 80 wt %, based on the ligand density of the quantum dot. When the quantum dot is substituted only with the metal halide, the metal halide may be present on the quantum dot surface in a range of about 10 wt % to about 80 wt %, based on the ligand density of the quantum dot. When ligand substitution is performed using the aliphatic hydrocarbon compound substituted with the hydroxyl group and the thiol group and the metal halide together, the total amount of the two materials may be in the range of about 10 wt % to about 80 wt %, based on the ligand density of the quantum dot.

In an embodiment, when ligand substitution is performed using the aliphatic hydrocarbon compound substituted with the hydroxyl group and the thiol group, and the metal halide together, the amount of the aliphatic hydrocarbon compound substituted with the hydroxyl group and the thiol group may be in a range of about 5 wt % to about 70 wt %, and the amount of the metal halide may be in a range of about 1 wt % to about 50 wt %, for example, the amount of the aliphatic hydrocarbon compound substituted with the hydroxyl group and the thiol group may be in a range of, for example, about 5 wt % to about 50 wt %, about 10 wt % to about 50 wt %, or about 10 wt % to about 30 wt %, and the amount of the metal halide may be in a range of about 1 wt % to about 40 wt %, for example, about 1 wt % to about 30 wt %, about 2 wt % to about 30 wt %, about 3 wt % to about 30 wt %, or about 3% to about 20 wt %.

As can be seen from Examples described herein, the quantum dot substituted with ligands in the disclosed range may have the same absorption peak wavelength as the quantum dot before ligand substitution, but the photoluminescence intensity, the charge mobility of the thin film or device including the quantum dot, or the external quantum efficiency (EQE), for example, may be further increased, and the HOMO energy level may be further deepened. Without wishing to be bound by any theory, it is believed that such changes are due to, for example, the fact that the aliphatic hydrocarbon compound substituted with the hydroxyl and thiol groups is a relatively short ligand, which may further increase charge mobility, the metal halide may more effectively passivate the surface of the quantum dot according to an embodiment, or a combination thereof.

The method for preparing a quantum dot according to an embodiment is a method that may enable highly reproducible preparing of quantum dot having an absorption peak wavelength of greater than or equal to about 1,100 nm and less than or equal to about 1,600 nm in the visible-infrared absorption spectrum and having a uniform size and shape, and by further substituting the surface ligand of the quantum dot prepared as described herein, the charge mobility and external quantum efficiency of an electronic device including the quantum dot may be significantly improved. The quantum dot prepared by the preparing method according to an embodiment may be advantageously used in solar cells, image sensors, and light absorption layers of infrared sensors (IR sensors) that include the quantum dot in a semiconductor layer, channel materials of field effect transistors (FETs), light emitting materials of near-infrared quantum dot light emitting diodes (NIR QD LEDs), and thermoelectric materials.

An embodiment provides a quantum dot prepared by the disclosed preparing method.

The quantum dot according to an embodiment is a quantum dot that includes elements of Group IIIA and Group VA of the periodic table of elements, does not include hazardous heavy metals such as mercury, cadmium, or lead, and has an absorption peak wavelength of greater than or equal to about 1,100 nm and less than or equal to about 1,600 nm in a Vis-IR absorption spectrum.

As described herein, desired is a quantum dot that does not contain heavy metals such as lead and exhibits excellent light absorption characteristics in the SWIR region. The quantum dot according to an embodiment has a long-wavelength absorption peak wavelength of greater than or equal to about 1,100 nm and less than or equal to about 1,600 nm in the Vis-IR absorption spectrum, and may be used as an IR absorbing material that absorbs light in the infrared region.

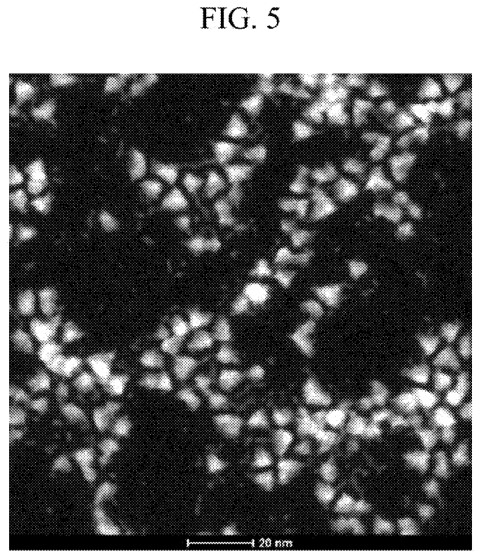

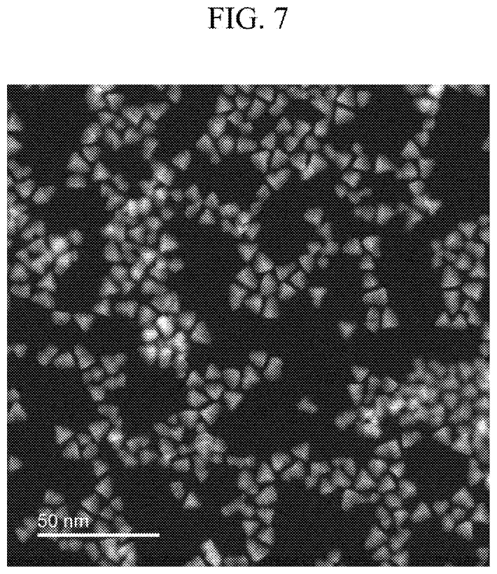

The quantum dot according to an embodiment may exhibit the formation of a superlattice structure in transmission electron microscopy analysis. As can be seen from the transmission electron microscope (TEM) images of FIG. 5, and FIG. 7, the quantum dot according to an embodiment has a very uniform size and shape, and excellent characteristics of an electronic device including the quantum dot according to an embodiment may be achieved.

In an embodiment, the quantum dot may have an absorption peak wavelength in a Vis-IR absorption spectrum of greater than or equal to about 1,100 nm, for example, greater than or equal to about 1,150 nm, greater than or equal to about 1,180 nm, greater than or equal to about 1,200 nm, greater than or equal to about 1,250 nm, greater than or equal to about 1,300 nm, greater than or equal to about 1,350 nm, greater than or equal to about 1,400 nm, greater than or equal to about 1,450 nm, greater than or equal to about 1,500 nm, or greater than or equal to about 1,550 nm. The quantum dot according to an embodiment may have an absorption peak wavelength in a Vis-IR absorption spectrum of less than or equal to about 1,600 nm, for example, less than or equal to about 1,550 nm, less than or equal to about 1,500 nm, less than or equal to about 1,450 nm, less than or equal to about 1,400 nm, less than or equal to about 1,350 nm, less than or equal to about 1,300 nm, less than or equal to about 1,250 nm, less than or equal to about 1,200 nm, less than or equal to about 1,190 nm, less than or equal to about 1,180 nm, less than or equal to about 1,150 nm, or less than or equal to about 1,130 nm. The quantum dot according to an embodiment may have, in the Vis-IR absorption spectrum, an absorption peak wavelength of about 1,100 nm to about 1,600 nm, about 1,150 nm to about 1,550 nm, about 1,150 nm to about 1,500 nm, about 1,180 nm to about 1,550 nm, about 1,180 nm to about 1,500 nm, about 1,180 nm to about 1,450 nm, about 1,200 nm to about 1,550 nm, about 1,200 nm to about 1,500 nm, about 1,200 nm to about 1,450 nm, about 1,200 nm to about 1,400 nm, about 1,200 nm to about 1,350 nm, about 1,250 nm to about 1,550 nm, about 1,250 nm to about 1,500 nm, about 1,250 nm to about 1,450 nm, about 1,250 nm to about 1,400 nm, about 1,300 nm to about 1,550 nm, about 1,300 nm to about 1,500 nm, about 1,300 nm to about 1,450 nm, about 1,300 nm to about 1,400 nm, about 1,350 nm to about 1,600 nm, about 1,350 nm to about 1,550 nm, about 1,350 nm to about 1,500 nm, about 1,380 nm to about 1,550 nm, about 1,380 nm to about 1,500 nm, about 1,380 nm to about 1,450 nm, about 1,400 nm to about 1,600 nm, about 1,400 nm to about 1,550 nm, about 1,400 nm to about 1,500 nm, about 1,450 nm to about 1,600 nm, or about 1,450 nm to about 1,550 nm.

The average particle size of the quantum dot may be greater than or equal to about 2.5 nm.

As described herein, the bandgap energy of the quantum dot may be controlled by controlling the particle size and composition thereof, the size of the quantum dot may be controlled, and the quantum dot according to an embodiment may have an absorption peak wavelength in the range of greater than or equal to about 1,100 nm and less than or equal to about 1,600 nm. For example, the average particle size of the quantum dot may be greater than or equal to about 2.5 nm, greater than or equal to about 2.7 nm, greater than or equal to about 3.0 nm, greater than or equal to about 3.2 nm, greater than or equal to about 3.5 nm, greater than or equal to about 3.7 nm, greater than or equal to about 4.0 nm, greater than or equal to about 4.2 nm, greater than or equal to about 4.5 nm, greater than or equal to about 4.7 nm, greater than or equal to about 5.0 nm, greater than or equal to about 5.2 nm, greater than or equal to about 5.5 nm, greater than or equal to about 5.7 nm, greater than or equal to about 6.0 nm, greater than or equal to about 6.5 nm, greater than or equal to about 7.0 nm, greater than or equal to about 7.5 nm, greater than or equal to about 8.0 nm, greater than or equal to about 8.5 nm, greater than or equal to about 9.0 nm, greater than or equal to about 9.5 nm, greater than or equal to about 10.0 nm, greater than or equal to about 10.5 nm, greater than or equal to about 11.0 nm, greater than or equal to about 11.5 nm, greater than or equal to about 12 nm, greater than or equal to about 13 nm, greater than or equal to about 15 nm, greater than or equal to about 17 nm, greater than or equal to about 18 nm, or greater than or equal to about 19 nm. The average particle size of the quantum dot may be less than or equal to about 30 nm, for example, less than or equal to about 28 nm, less than or equal to about 25 nm, less than or equal to about 23 nm, less than or equal to about 20 nm, less than or equal to about 18 nm, less than or equal to about 17 nm, less than or equal to about 15 nm, less than or equal to about 13 nm, less than or equal to about 12 nm, less than or equal to about 11 nm, less than or equal to about 10 nm, less than or equal to about 9.5 nm, less than or equal to about 9 nm, less than or equal to about 8.5 nm, less than or equal to about 8 nm, less than or equal to about 7.5 nm, less than or equal to about 7 nm, less than or equal to about 6.5 nm, less than or equal to about 6 nm, less than or equal to about 5.5 nm, less than or equal to about 5.0 nm, less than or equal to about 4.5 nm, less than or equal to about 4.0 nm, less than or equal to about 3.5 nm, less than or equal to about 3.0 nm, or less than or equal to about 2.7 nm.

The Group IIIA element and the Group VA element included in the quantum dot according to an embodiment are as described for the method for preparing the quantum dot according to an embodiment.

In an embodiment, the Group IIIA element included in the quantum dot may be indium (In), and the Group VA element included in the quantum dot may be arsenic (As). For example, the quantum dot may include indium (In) and arsenic (As), and optionally further include gallium (Ga), antimony (Sb), or a combination thereof. For example, the quantum dot may include indium (In) and arsenic (As), and optionally further include antimony (Sb). For example, the quantum dot may be composed of indium (In) and arsenic (As).

In an embodiment, the quantum dot may have a molar ratio of the Group VA element (e.g., arsenic) to the Group IIIA element (e.g., indium) of greater or equal to about 0.5:1.0, for example, greater or equal to about 0.55:1.0, greater or equal to about 0.6:1.0, greater or equal to about 0.65:1.0, greater or equal to about 0.7:1.0, greater or equal to about 0.75:1.0, greater or equal to about 0.8:1.0, greater or equal to about 0.85:1.0, greater or equal to about 0.9:1.0, or greater or equal to about 0.95:1.0, and also less than or equal to about 1.0:1.0, for example, less than or equal to about 0.95:1.0, less than or equal to about 0.9:1.0, less than or equal to about 0.85:1.0, less than or equal to about 0.8:1.0, less than or equal to about 0.75:1.0, less than or equal to about 0.7:1.0, less than or equal to about 0.65:1.0, less than or equal to about 0.6:1.0, or less than or equal to about 0.55:1.0. For example, the molar ratio of the Group IIIA element to the Group VA element in the quantum dot may be about 1:1 to about 2:1, for example, about 1:1 to about 1.8:1, about 1:1 to about 1.7:1, about 1:1 to about 1.6:1, about 1:1 to about 1.5:1, about 1:1 to about 1.4:1, about 1:1 to about 1.3:1, about 1:1 to about 1.2:1, about 1:1 to about 1.1:1, for example, about 1:1.

A molar ratio of elements in the quantum dot may be confirmed by, for example, inductively coupled plasma-mass spectrometry (ICP-MS) or energy dispersive spectroscopy (EDS).

A quantum dot according to an embodiment may include an amine compound, a phosphine compound, or a combination thereof on a surface thereof.

The amine compound and phosphine compound are the same as the first amine compound, second amine compound, and phosphine compound included in the precursor solution used in the preparation of the quantum dot according to an embodiment.

As described herein, the quantum dot prepared by the method for preparing a quantum dot according to an embodiment may include, on a surface of the quantum dot before ligand substitution, materials that form a precursor solution used in preparing the quantum dot, for example, a first amine compound, a second amine chemical, a phosphine compound, or a combination thereof. As can be seen from Examples described herein, the Vis-IR absorption spectra of quantum dots including the amine compound, the phosphine compound, or a combination thereof included in the precursor solution used in the production of the quantum dots on the surface demonstrate that the absorption peak wavelength of the quantum dots may be greater than or equal to about 1,200 nm. The quantum dot according to an embodiment may have an absorption peak wavelength of greater than or equal to about 1,100 nm, for example, greater than or equal to about 1,200 nm, in the Vis-IR absorption spectrum by being prepared by the preparing method according to an embodiment.

As can be seen from Comparative Examples described herein, even if quantum dots are prepared using the same precursors and reacting the precursors at the same final reaction temperature, if the precursors are mixed and reacted directly at the final reaction temperature of the precursors, the Vis-IR absorption spectrum of the quantum dots prepared therefrom cannot exhibit an absorption peak at a specific wavelength, but can only exhibit a broad absorption graph over a wide wavelength range. Even if a quantum dot is prepared from the same precursor and include the same ligand on the surface, it may be difficult to prepare a quantum dot having an absorption peak wavelength of greater than or equal to about 1,100 nm and less than or equal to about 1,600 nm if the quantum dot is not prepared using a preparing method according to an embodiment.

The quantum dot according to an embodiment may include a ligand derived from the aliphatic hydrocarbon compound substituted with the hydroxyl group (—OH) and the thiol group (—SH), the metal halide, or the combination thereof on a surface thereof instead of the amine compound, the phosphine compound, or a combination thereof. The method of replacing the surface ligand of a quantum dot according to an embodiment with a ligand derived from the aliphatic hydrocarbon compound substituted with the hydroxyl group and the thiol group, the metal halide, or a combination thereof is as described herein. By bringing a polar solvent including the compound and a non-polar solvent including a quantum dot including the amine compound, phosphine compound, or a combination thereof on the surface into contact with each other to cause a phase transition, a quantum dot may be obtained in which a ligand derived from the aliphatic hydrocarbon compound substituted with the hydroxyl group and thiol group, the metal halide, or a combination thereof are present on the surface of the quantum dot instead of the amine compound, phosphine compound, or a combination thereof present on the surface of the quantum dot.

The ligand derived from an aliphatic hydrocarbon compound substituted with a hydroxyl group (—OH) and a thiol group (—SH) present on the surface of a quantum dot according to an embodiment may be derived from a linear or branched aliphatic hydrocarbon compound having 2 to 30 carbon atoms substituted with a, e.g., one or more, hydroxyl group and a, e.g., one or more, thiol group. For example, the ligand may be derived from a linear or branched aliphatic hydrocarbon compound having 2 to 20 carbon atoms substituted with a, e.g., one or more, hydroxyl group and a, e.g., one or more, thiol group, or may be derived from a linear or branched aliphatic hydrocarbon compound having 2 to 10 carbon atoms substituted with a, e.g., one or more, hydroxyl group and a, e.g., one or more, thiol group. In an embodiment, the compound may be, for example, 1-hydroxy-2-mercaptoethane (ME), 1,2-dihydroxy-3-mercapto propane (MPD), or a combination thereof.

Without intending to be bound by a particular theory, the smaller the carbon number of the aliphatic hydrocarbon compound from which the ligand is derived, i.e., when the quantum dot surface is modified with a ligand having a shorter carbon chain length, the charge mobility of the electronic device including the quantum dot may further increase. When the carbon number of the ligand is reduced to include a shorter ligand, dispersion of the quantum dot in the solvent may be difficult. There is also a possibility that the external quantum efficiency (EQE) may decrease due to, for example, aggregation of quantum dot. By controlling the carbon number of the ligand present on the surface of a quantum dot according to an embodiment, the electrical characteristics, external quantum efficiency, or a combination thereof of a device including the quantum dot may be controlled.

The metal halide present on the surface of the quantum dot according to an embodiment may include a halide of a Group IIIA metal, a halide of a Group IIA metal, or a combination thereof. For example, the halide of the Group IIIA metal may include a halide of indium (In), such as InBr, InI, InCl, or a combination thereof. The halide of the Group IIA metal may include a halide of zinc (Zn), for example, ZnCl₂, ZnI₂, ZnBr₂, or a combination thereof.

Without wishing to be bound by any theory, it is believed that when a quantum dot according to an embodiment further includes the metal halide as described herein on a surface thereof, the metal halide has the effect of passivating surface defects of the quantum dot. As can be seen from Examples described herein, without wishing to be bound by any theory, it is believed that the photoluminescence characteristics of the quantum dot may be further improved, the energy levels may be controlled to exhibit deeper HOMO energy, and surface passivation may further enhance charge mobility.

The amounts of ligands that may exist on the surface of the quantum dot is the same as described herein, and a detailed description thereof is omitted.

An embodiment provides an electronic device including the quantum dot described herein.

The electronic device may include a solar cell, a photodetector, a field effect transistor, a flash memory, a photoelectrochemical device, or a combination thereof. The quantum dot according to an embodiment may be applied to a light absorbing layer or a semiconductor layer of a solar cell and a photodetector, and absorb light in the visible light range and near-infrared region to generate electrical energy and signals. The quantum dot may be used as n-type or p-type channel layers of transistors and may also be applied to floating gates of flash memory. The quantum dot may also be applied to the photoelectric conversion layer of a photoelectrochemical cell that receives light, decomposes water to produce hydrogen and oxygen, or reduces CO₂ to produce organic compounds.

An electronic device according to an embodiment includes a first electrode and a second electrode spaced apart from each other; and a semiconductor layer including the disclosed quantum dot between the first electrode and the second electrode.

The first electrode and the second electrode may have main surfaces facing each other, and the semiconductor layer may be interposed between the first electrode and the second electrode. The semiconductor layer may be electrically connected to the first electrode, the second electrode, or a combination thereof.

A thickness of the semiconductor layer may be greater than or equal to about 10 nm, for example, greater than or equal to about 20 nm, greater than or equal to about 30 nm, greater than or equal to about 40 nm, greater than or equal to about 50 nm, or greater than or equal to about 100 nm. The thickness of the semiconductor layer may be less than or equal to about 1 μm, for example, less than or equal to about 900 nm, less than or equal to about 800 nm, less than or equal to about 700 nm, less than or equal to about 600 nm, less than or equal to about or 500 nm, less than or equal to about 400 nm, less than or equal to about 300 nm, less than or equal to about 200 nm, less than or equal to about 100 nm, or less than or equal to about or 60 nm.

In an electronic device of an embodiment, the semiconductor layer may absorb near-infrared light of greater than or equal to about 1,100 nm, for example, from about 1,100 nm to about 1,600 nm, from about 1,150 nm to about 1,600 nm, from about 1,200 nm to about 1,600 nm, from about 1,200 nm to about 1,550 nm, from about 1,200 nm to about 1,500 nm, from about 1,200 nm to about 1,450 nm, from about 1,250 nm to about 1,450 nm, or from about 1,300 nm to about 1,450 nm, and a photocurrent may be generated.

The semiconductor layer of the electronic device may have a charge mobility of greater than or equal to about 10-4 square centimeters per volt-second (cm²/Vs), for example, greater than or equal to about 10-3 cm²/VNs, for example, greater than or equal to about 1×10⁻² cm²/Vs. As can be seen from Examples described herein, an electronic device including a quantum dot in a semiconductor layer according to an embodiment may have a faster charge mobility as the absorption peak wavelength of the quantum dot becomes longer or the size of the quantum dot becomes larger. Such an effect may not be expected from quantum dots formed in an anisotropic shape as the particle size of the quantum dot increases. The quantum dot according to an embodiment may maintain an isotropic shape and have a uniform particle size distribution even when the particle size of the quantum dot increases.

In an electronic device of an embodiment, the semiconductor layer may be configured to have a responsivity of greater than or equal to greater than or equal to about 1×10⁻¹ amperes per watt (A/W), or greater than or equal to about 2×10⁻¹ A/W when irradiated with light having a wavelength of about 1.55 μm.

In an electronic device of an embodiment, the semiconductor layer may be configured to have an external quantum efficiency (EQE) of greater than or equal to about 10% when irradiated with light having a wavelength of 1.55 μm.

The electronic device may include a carrier auxiliary layer between the semiconductor layer and the first electrode, between the semiconductor layer and the second electrode, or both. The carrier auxiliary layer may include a metal oxide. The metal oxide may include molybdenum metal oxide, zinc metal oxide, or a combination thereof.

In an embodiment, the electronic device may be a field effect transistor (FET). The electronic device may further include a third electrode facing the semiconductor layer; and an insulating layer between the semiconductor layer and the third electrode.

The electronic device may be configured to have a field effect mobility of greater than or equal to about 10⁻⁴ cm²/Vs. The electronic device may be configured to have a field effect mobility of greater than or equal to about 1.2×10⁻⁴ cm²/Vs, for example, greater than or equal to about 1.29×10⁻⁴ cm²/Vs, greater than or equal to about 1.59×10⁻⁴ cm²/Vs, greater than or equal to about 3.0×10⁻⁴ cm²/Vs, greater than or equal to about 3.45×10⁻³ cm²/Vs, greater than or equal to about 1.0×10⁻² cm²/Vs, or greater than or equal to about 1.30×10⁻² cm²/Vs.

In an embodiment, the semiconductor layer may be in contact with the first electrode and the second electrode. The first electrode and the second electrode may be arranged to form an interdigitated form. The spacing between the first electrode and the second electrode may be greater than or equal to about 1 μm, for example, greater than or equal to about 2 μm, greater than or equal to about 3 μm, greater than or equal to about 4 μm, or greater than or equal to about 5 μm.

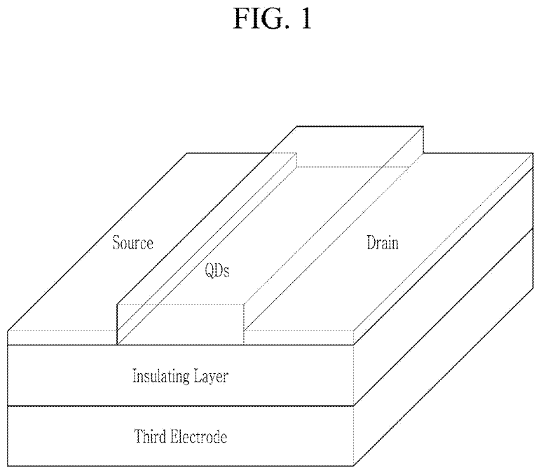

FIG. 1 is a schematic perspective view of an electronic device according to an embodiment. Referring to FIG. 1, a semiconductor layer including a quantum dot including a Group IIIA element and a Group VA element according to an embodiment is disposed between a first electrode (e.g., a source electrode) and a second electrode (e.g., a drain electrode). The electronic device further includes a third electrode (e.g., a gate electrode) facing the semiconductor layer, and an insulating layer is disposed between the semiconductor layer and the third electrode.

Materials for the first electrode and the second electrode may be appropriately selected. Examples of the materials for the first electrode and the second electrode include a metal such as gold, nickel, aluminum, and platinum, a conductive polymer, or conductive ink. Each thickness of the first electrode and the second electrode may be appropriately selected. For example, the thickness of the first electrode (or the second electrode) may be greater than or equal to about 40 nm, for example, greater than or equal to about 100 nm and less than or equal to about 400 μm.

The material of the third electrode (e.g., gate electrode) may be appropriately selected. For example, the third electrode may include a metal film, a conductive polymer film, a conductive film made of conductive ink or paste, or doped silicon. Examples of the material of the third electrode may include a conductive polymer such as poly(3,4-ethylene dioxythiophene) doped with polystyrene sulfonate (PSS-PEDOT), aluminum, gold, silver, chromium, or indium tin oxide, a conductive ink/paste such as a carbon black/graphite or colloidal silver dispersion or a silver inks (Ag ink) in polymer binders. The third electrode layer may be manufactured by vacuum deposition or sputtering of a metal or a conductive metal oxide, spin coating of a conductive polymer solution or conductive ink, coating by casting or printing, or doping of a substrate. A thickness of the third electrode layer may be appropriately selected. For example, the thickness of the third electrode including a metal thin film may be greater than or equal to about 10 nm and less than or equal to 200 nm, the third electrode including a polymer conductor may be about 1 μm to about 10 μm, and the thickness of the gate electrode including a carbon composite such as a carbon nanotube (CNT) may be greater than or equal to about 100 nm, for example, about 1 μm to about 10 μm.

The insulating layer separates the third electrode from the first electrode, the second electrode, and the semiconductor layer 30. The insulating layer may include a thin film of an inorganic material or a film of an organic polymer. Examples of inorganic materials include silicon oxide, silicon nitride, aluminum oxide, barium titanate, or zirconium titanate. Examples of organic polymers may include polyester, polycarbonate, poly(vinyl phenol), polyimide, polystyrene, poly(methacrylate), poly(acrylate), or an epoxy resin. A thickness of the insulating layer may vary depending on the permittivity of the insulating material. For example, the insulating layer may have a thickness of greater than or equal to about 10 nm, for example, greater than or equal to about 50 nm, or greater than or equal to about 100 nm. The insulating layer may have a thickness of, for example, less than or equal to about 2,000 nm, for example, less than or equal to about 500 nm. The conductivity of the insulating layer may be, for example, less than or equal to about 10⁻¹² siemens per centimeter (S/cm).

The first electrode, the semiconductor layer, the insulating layer, the third electrode, and the second electrode may be formed in any suitable order.

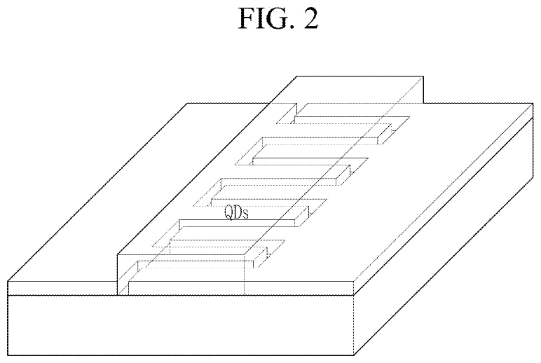

FIG. 2 is a schematic perspective view of an electronic device according to an embodiment. Referring to FIG. 2, the electronic device includes a first electrode and a second electrode spaced apart from each other, and a semiconductor layer including a quantum dot according to an embodiment between the first and second electrodes. The semiconductor layer is in contact with the first and second electrodes. The description of the electrodes and semiconductor layers is as described in FIG. 1.

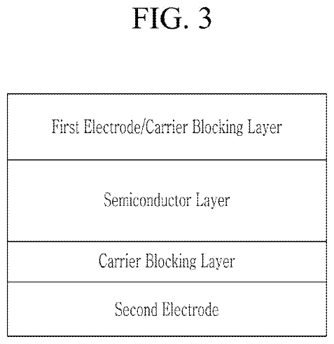

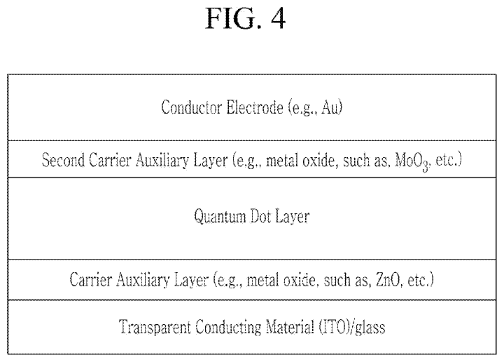

FIGS. 3 and 4 illustrate cross-sectional views of electronic devices according to an embodiment, respectively. Referring to FIGS. 3 and 4, the device includes a semiconductor layer disposed between a first electrode (e.g., indium tin oxide) and a second electrode (e.g., aluminum). The semiconductor layer may include the quantum dot according to an embodiment. The device may form a metal-semiconductor Schottky junction or heterojunction photodiode. The semiconductor layer may include a layer exhibiting p-type characteristics. The semiconductor layer may include a layer exhibiting n-type characteristics. The semiconductor layer may include a layer exhibiting i-type characteristics. The semiconductor layer is a multilayer structure, and each layer may be configured to represent n type, i type, p type, or a combination thereof. A carrier auxiliary layer (a carrier transport layer, a carrier injection layer, or a carrier blocking layer, such as PSS-PEDOT, a metal oxide, or LiF) may be disposed between the semiconductor layer and the first electrode, between the semiconductor layer and the second electrode, or both. The metal oxide may include, for example, zinc oxide, molybdenum oxide, or a combination thereof. The device may include a Schottky diode.

In FIGS. 3 and 4, the first electrode and the second electrode are shown as being positioned at the upper and lower portions of each drawing, respectively, but the positions of each electrode may not have fixed positions such as the actual upper or lower portions. The first electrode shown in FIG. 3 may be positioned at the bottom, and the second electrode may be positioned at the top, or the transparent conductor of FIG. 4 may be positioned at the top of the device, a carrier auxiliary layer including ZnO may be positioned therebelow, a conductor electrode may be positioned at the bottom, and a second carrier auxiliary layer (a layer including MoO₃) may be positioned thereon.

Specific examples are presented below. However, the examples described below are only intended to specifically illustrate or explain the above embodiments, and the scope of the present specification should not be limited thereby.

### Examples

### Measurement Methods

### [1] Photoluminescence Analysis of Quantum Dot

Photoluminescence (PL) spectra of the prepared quantum dots are obtained by using a photoluminescence analyzer (Model name: FLS1000, Manufacturer: Edinburgh Instruments Ltd.).

### [2] Ultraviolet (UV)-Visible (Vis)-Near-Infrared (NIR) Spectral Analysis

UV-Visible-NIR absorption spectra are obtained using a UV-Visible-NIR spectrophotometer.

### [3] TEM Analysis

A transmission electron microscope (Model name: JEM1400, Manufacturer: JEOL Inc.) is used to perform a transmission electron microscope analysis.

### [4] Measurement of Electrical and Photoelectric Properties

A semiconductor parameter analyzer (Model name: 4156C manufactured by Agilent Technologies) is used to measure electrical and photoelectric properties.

### [5] Inductively Coupled Plasma-Mass Spectrometry Analysis

Inductively coupled plasma-mass spectrometry is performed using Element II HR-ICP-MS.

### Reference Example 1 and Example 1: Preparation of InAs Quantum Dot Passivated with Oleylamine

An amount of 7.2 milliliters (ml) of oleylamine and 0.225 grams (g) of In(I)Cl as an indium precursor are added to a 50 ml 3-neck flask, and degassing is performed at 60 °C for 30 minutes. When the degassing is completed, after purging with nitrogen inside the flask, 0.3 ml of trioctyl phosphine (TOP) is injected thereinto. After the TOP injection, the reactant in the flask is rapidly heated up to 270 °C within 10 minutes.

In the glove box, 2 ml of oleylamine and 0.15 ml of tris(dimethylamino)arsine as a precursor compound of arsenic (As) are added to a 10 ml vial and then, heated at 50 °C for 10 minutes.

When the temperature of the reactant in the flask containing the indium precursor reaches 270 °C, 1.3 ml of the solution including the arsenic precursor in the vial is extracted and injected into the flask including the indium precursor. After the injection, the mixture is reacted at the temperature (270 °C) for 10 minutes, preparing a quantum dot of Reference Example 1. The quantum dot of Reference Example 1 may be obtained, after extracting a portion of the reactant reacted at 270 °C for 10 minutes in a similar manner to that of Example 1, by adding a mixture of hexane and n-butanol (in a volume ratio of 1:10) as a nonsolvent thereto and centrifuging the extracted reactant.

Simultaneously with the extraction, the reactant in the flask may be further reacted for 1 hour at 300 °C by rapidly increasing the temperature from 270 °C to 300 °C within 5 minutes. Subsequently, the reactant is cooled to room temperature. Then, 2 ml and 20 ml of hexane and n-butanol are respectively added to the crude solution extracted from the flask and then, centrifuged at 6,000 revolutions per minute (rpm) for 5 minutes to obtain the quantum dot. The obtained quantum dot is added again to a mixture of 10 mL of hexane and 30 ml of n-butanol and then, centrifuged again at 6,000 rpm for 5 minutes to obtain the quantum dot of Example 1.

The separated quantum dot of Example 1 is measured with TEM, and the result is shown in FIG. 5. As seen from FIG. 5, the quantum dot of Example 1 has an overall uniform shape and an average particle diameter of about 6.5 nanometers (nm).

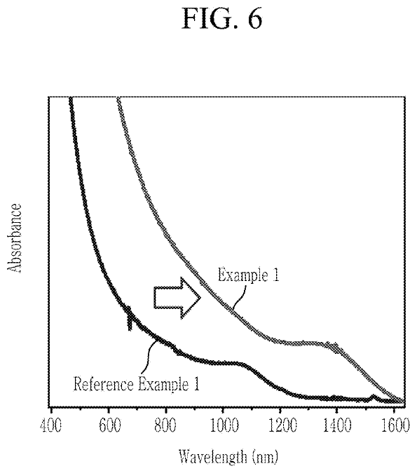

In addition, the quantum dot of Reference Example 1 and the quantum dot of Example 1 are measured with respect to Vis-IR absorption spectra, and the results are shown in FIG. 6.

As seen from FIG. 6, the quantum dot of Reference Example 1, in which an arsenic precursor and an indium precursor are mixed at 270 °C and reacted for 10 minutes, exhibits an absorption peak wavelength of less than 1,100 nm, while the quantum dot of Example 1, in which after the reaction, the mixture is further reacted for 1 hour by increasing the temperature to 300 °C within 5 minutes, exhibits an absorption spectrum overall shifted toward long wavelengths and having a significantly longer absorption peak wavelength of greater than 1,300 nm. A quantum dot prepared by mixing precursors of the quantum dot at a lower temperature than a final reaction temperature to primarily react the precursors and then, increasing the temperature to a final reaction temperature within a short period of time to additionally react the precursors exhibits a better absorption peak at a longer wavelength than a quantum dot prepared by the primary reaction alone (the quantum dot of Reference Example 1). By mixing precursors of the quantum dot at the lower temperature than the final reaction temperature to primarily react the precursors and then, increasing the temperature to the final reaction temperature within the short period of time to additionally react the precursors results in a quantum dot having a uniform size and shape as shown in FIG. 5.

The quantum dot of Example 1 is measured with respect to an indium (In) content and an arsenic (As) content by using inductively coupled plasma-mass spectrometry (ICP-MS), and the results are shown in Table 1.

TABLE 1

| | In | As | In:As |
|---|---|---|---|
| Number of moles | 0.53 | 0.47 | 1.13:1 |

As shown in Table 1, the In content is larger than the As content in the quantum dot prepared according to the present embodiment.

### Reference Example 2 and Example 2: Preparation of InAs Quantum Dot Passivated with Oleylamine

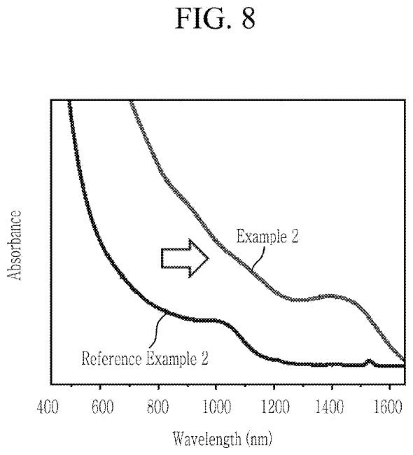

A quantum dot of Example 2 is prepared in the same manner as in Example 1 except that after mixing the indium precursor and the arsenic precursor at 270 °C and reacting the indium precursor and the arsenic precursor for 10 minutes, the reaction is further performed for 1 hour by increasing the temperature to 310 °C within 5 minutes. A TEM image and a Vis-IR absorption spectrum of the prepared quantum dot of Example 2 are respectively shown in FIGS. 7 and 8. In addition, the quantum dot of Reference Example 2 is obtained from the reactant extracted after reacting at 270 °C for 10 minutes in the same manner as in Reference Example 1.

FIG. 7 shows a similar particle shape to that of FIG. 5, but the particle shape and size are larger and more uniform than that of FIG. 5.

In addition, in the spectra of FIG. 8, the quantum dot of Reference Example 2 prepared by reacting at 270 °C for 10 minutes exhibits an absorption peak wavelength slightly exceeding 1,000 nm, but the quantum dot of Example 2 obtained from further reacting for 1 hour by increasing the temperature to 310 °C within 5 minutes exhibits that the absorption spectrum is overall shifted toward a long wavelength and has a good absorption peak around about 1,400 nm. It is confirmed that the reaction temperature may be further increased to 310 °C to prepare a quantum dot having a longer absorption peak wavelength than that of Example 1.

### Comparative Example 1: Preparation of InAs Quantum Dot Passivated with Oleylamine

A quantum dot of Comparative Example 1 is prepared by using the same precursor solutions as Examples 1 and 2 except that when the indium precursor solution is set at a temperature of 310 °C, the arsenic precursor is injected thereinto and then, reacted at this temperature for more than or equal to 20 minutes.

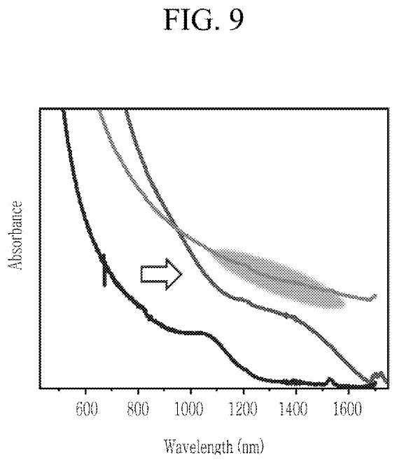

The quantum dot of Comparative Example 1 is measured with respect to a Vis-IR absorption spectrum, which is shown in FIG. 9. In FIG. 9, the graph at the left is an absorption spectrum of the quantum dot obtained by the reaction for 10 minutes after injecting the precursor, and the graph at the right is an absorption graph of the quantum dot obtained by performing the reaction further for 10 minutes, that is, for 20 minutes in total, wherein the absorption graph is shifted toward a long wavelength. In addition, the graph between the described two graphs and crossing the graph at the right is an absorption spectrum of the quantum dot obtained by reacting the reactant for 20 minutes or more at the temperature.

As shown in FIG. 9, unlike Examples 1 and 2, when the two precursor solutions are mixed at 310 °C and then, reacted, the quantum dot from the reaction for first 10 minutes exhibits similar absorption spectra to those of Reference Examples 1 and 2, but when the reaction is performed further for 10 minutes at the same temperature without increasing the temperature, the absorption spectrum is shifted toward a long wavelength but exhibits no clear absorption peak. In addition, the quantum dot obtained by the reaction at the temperature up to 20 minutes or more exhibits a broader absorption spectrum with no peak at all. When mixed at 310 °C and continuously reacted, the quantum dot may not have the same long absorption peak wavelength as those of the examples.

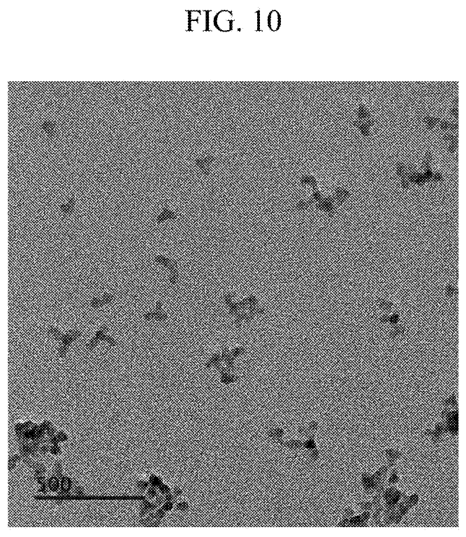

In addition, FIG. 10 shows a TEM image of the quantum dot prepared by reacting at the disclosed temperature for 20 minutes. Referring to FIG. 10, the quantum dot of Comparative Example 1, unlike the quantum dots of Examples 1 and 2 shown in FIGS. 5 and 7, is confirmed to have an anisotropic and non-uniform particle shape and size.

If the quantum dot precursors are mixed at a high reaction temperature of a final reaction temperature and continuously reacted at the corresponding temperature, a quantum dot with uniform size and shape may not be obtained, and, as shown in FIG. 9, if the reaction time is short, a quantum dot with an absorption peak wavelength of about 1,100 nm may be prepared, but even if the reaction time is further increased, a quantum dot with an absorption peak wavelength of 1,100 nm or higher in a Vis-IR absorption spectrum may not be prepared, wherein the absorption spectrum may become gradually broader and then, disappear.

### Example 3: Preparation of InAs Quantum Dot Ligand-Substituted with 3-mercapto-1,2-propanediol (MPD) and ZnCl₂

The quantum dot passivated with oleylamine (InAs-Olam) according to Example 2 is subjected to surface ligand substitution.

Specifically, 50 mg of the quantum dot surface-passivated with oleylamine (InAs-Olam) in Example 2 is dispersed in 2 ml of octane to prepare a quantum dot suspension.

In addition, 75 microliters (μl) of butylamine, 150 μl of 1-thioglycerol (3-mercapto-1,2-propanediol) (MDP), and 150 μl ZnCl₂ are dissolved in 2 ml of N, N-dimethylformamide (DMF) to prepare a ligand substitution solution.

The prepared quantum dot suspension is mixed with the prepared ligand substitution solution, and then, vortexed for 30 seconds to induce phase separation. Herein, if the phase separation is not clean, centrifugation is performed at 6,000 rpm for about 5 minutes.

A DMF layer is extracted from the phase separation layer, and then, three times vortexed with 2 ml of octane. Filtering may be performed to remove floating matters. Finally, a mixed solvent of DMF and toluene in a ratio of 1:2 is added thereto, and then, centrifuged at 6,000 rpm for 5 minutes to precipitate and separate the quantum dot.

### Example 4: Preparation of InAs Quantum Dot Ligand-Substituted with 3-mercapto-1,2-propanediol (MPD) and ZnCl₂

A ligand-substituted quantum dot is prepared by using the same method as Example 3 except that the content of ZnCl₂ of the ligand substitution solution is reduced to about % of that of Example 3 in the surface ligand substitution of the quantum dot passivated with oleylamine (InAs-Olam) of Example 2 with 3-mercapto-1,2-propanediol (MPD) and ZnCl₂.

### Example 5: Preparation of InAs Quantum Dot Substituted Only with 3-mercapto-1,2-propanediol (MPD)

A quantum dot is prepared by performing the surface ligand substitution of the quantum dot of Example 2 in the same method as in Example 3 but using a ligand substitution solution including the 3-mercapto-1,2-propanediol (MPD) alone but not ZnCl₂ unlike Example 3. The quantum dot of Example 5, compared to that of Example 3, includes MPD alone without ZnCl₂ as a ligand compound on the surface.

### Evaluation 1: Evaluation of Changes in Characteristics According to Surface Ligand Substitution of Quantum Dot

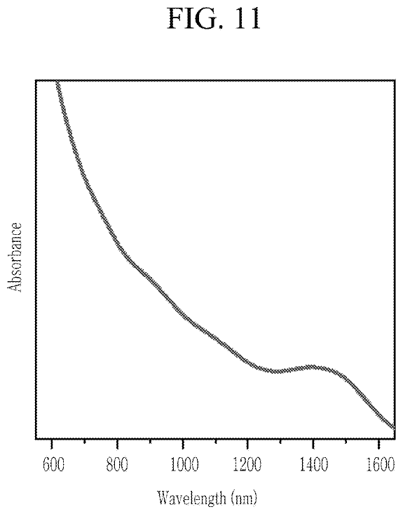

Three types of quantum dots according to Examples 3 to 5 are checked with respect to absorption and photoluminescence characteristics, and the results are shown in graphs of FIGS. 11 to 13.

FIG. 11 shows a Vis-IR absorption spectrum graph of the quantum dot prepared in Example 3. Referring to FIG. 11, the quantum dot of Example 3 prepared by substituting the surface ligand of the quantum dot of Example 2 with a different type of compound exhibits the same absorption spectrum as the quantum of Example 2. Even if the surface ligand of the quantum dot according to an embodiment is substituted with other types of ligands, the light absorption characteristics of the quantum dot are not changed but maintained.

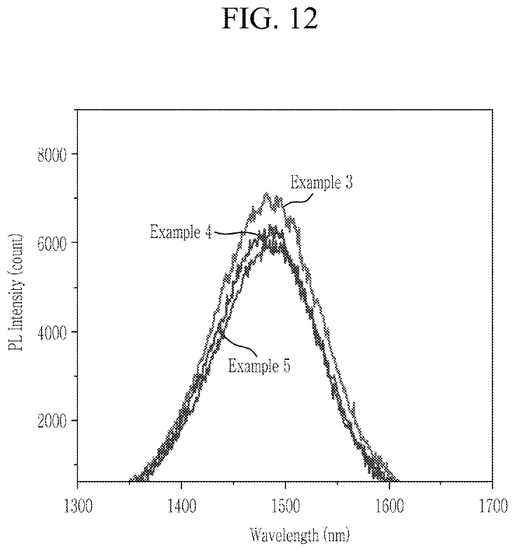

Referring to the photoluminescence spectra of FIG. 12, the quantum dots of Examples 3 and 4 including both MPD and ZnCl₂ exhibit much higher photoluminescence intensity than the quantum dot substituted with MPD alone according to Example 5, wherein the quantum dot of Example 3 having a higher ZnCl₂ content of 0.5 millimoles per liter (millimolar (mM)) exhibits higher photoluminescence intensity than that of Example 4 having a lower ZnCl₂ content of 0.25 millimoles per liter (millimolar (mM)). When the surface ligand of the quantum dot of Example 2 is substituted to include both MPD and ZnCl₂, the photoluminescence characteristics of the quantum dot may be improved, and in addition, the photoluminescence characteristics of the quantum dot may be improved by appropriately controlling the MPD and ZnCl₂ contents.

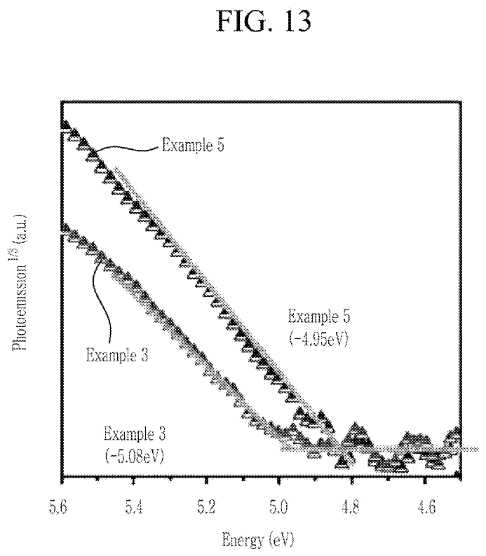

FIG. 13 is a graph showing intensity of photoelectrons generated from each thin film to energy applied to each thin film formed by including the quantum dots of Examples 3 and 5. The photoelectron generation intensity may be used to measure a work function and a highest occupied molecular orbital (HOMO) level of each of the quantum dots.

Referring to FIG. 13, the quantum dot of Example 3 prepared by substituting the surface ligand of the quantum dot of Example 2 with MPD and ZnCl₂ exhibits deeper photoelectron emission energy, that is, HOMO energy of −5.08 eV, than the HOMO energy of −4.95 electronvolts (eV) of quantum dot of Example 5 prepared by substituting the surface ligand of the quantum dot of Example 2 with MPD alone, and a photodiode including the quantum dot of Example 3 may be predicted to exhibit easier hole extraction. In addition, referring to FIG. 13, the ligand (oleylamine) of the quantum dot of Example 2 is confirmed to be substituted with MPD and ZnCl₂, and MPD alone in Examples 3 and 5, respectively.

The results demonstrate that the surface substitution of the quantum dot according to an embodiment may be used to adjust photoluminescence characteristics, energy levels, for example, HOMO energy levels or charge mobility, of the corresponding quantum dots. Without wishing to be bound by any theory, it is believed that the described effect is achieved by more efficiently passivating the surface of the quantum dot according to an embodiment with an aliphatic hydrocarbon compound substituted with a hydroxy group and a thiol group such as MPD and metal halide such as ZnCl₂. This ligand-substituted quantum dot may further improve electrochemical characteristics of an electronic device including the same.

### Experimental Example 1: Manufacturing and Evaluation of Field Effect Transistor (FETs)

The quantum dots according to Examples 3 and 5 are respectively used to manufacture a field effect transistor (FET). Specifically, after preparing a doped Si substrate having a SiO₂ gate oxide with a predetermined thickness, the quantum dot solutions according to Examples 3 and 5 are respectively coated thereon to form a semiconductor film. Subsequently, indium (In) and gold (Au) contacts are deposited at the left and right of the semiconductor film on the doped Si substrate to be used as a source electrode and a drain electrode, respectively.

The devices are manufactured under a dry nitrogen atmosphere, and the quantum dot solutions are dried at a predetermined temperature to dry solvents to form the semiconductor layer.

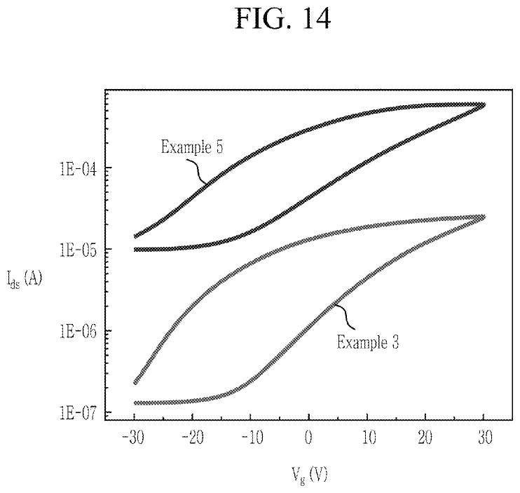

Each of the manufactured FET devices are measured with respect to electrical properties, and the results are shown in FIG. 14 and Table 2. FIG. 14 is a graph showing a drain current (Ids) to a gate voltage (Vg) (source-drain current versus gate voltage) of each of the devices. FIG. 14 shows electricity flows of the devices including the quantum dots according to Examples 3 and 5.

In addition, referring to the results of FIG. 14, the quantum dots of Examples 3 and 5 are measured with respect to charge mobility (N-type mobility), and the results are shown in Table 2.

TABLE 2

| | Mobility (square centimeters |
|---|---|
| | per volt-second (cm²/Vs)) |
| Example 3 | 2.59E−2 |
| Example 5 | 1.39E−2 |

Referring to Table 2, the FET devices including the quantum dots surface-modified with MPD and ZnCl₂, or MPD, according to Examples 3 and 5, as a semiconductor layer, exhibit very excellent charge mobility, and, for example, the FET device including the quantum dot surface-modified with both MPD and ZnCl₂ according to Example 3 as a semiconductor layer may exhibit twice times or greater the charge mobility of an FET device including the quantum dot surface-modified with MPD alone according to Example 5. Without wishing to be bound by any theory, it is believed that the results suggest that the quantum dot of Example 5 may achieve faster charge mobility by MPD, a shorter ligand with the smaller number of carbons on the surface, but the quantum dot of Example 3 may be more effectively surface-passivated by further including ZnCl₂ in addition to MPD on the surface and achieve much higher charge mobility.

A quantum dot, which is prepared by surface-substituting the quantum dot of Example 1 or 2 with MPD, similarly to that of Example 5, but controlling, for example, a reaction temperature or reaction time, during the preparation, is measured with respect to a Vis-IR absorption spectrum. As shown in Table 3, the smaller the particle size of the quantum dot, due to, for example, the lower temperature or the shorter time reaction, the shorter the Vis-IR absorption peak wavelength. In addition, the quantum dots having such absorption peak wavelengths are respectively used to manufacture field effect transistors (FET) including the quantum dots respectively in a semiconductor layer in the same manner as described herein. Such field effect transistors are respectively measured with respect to drain current (Ids) versus gate voltage (Vg) similarly to FIG. 14, which is used to calculate N-type mobility of each FET, and the results are shown in Table 3.

TABLE 3

| Vis-IR absorption peak wavelength | N-type mobility |
|---|---|
| of quantum dots (nm) | (cm²/Vs) |
| 1,180 nm | 1.29 E−4 |
| 1,230 nm | 1.59 E−4 |
| 1,300 nm | 3.45 E−3 |
| 1,330 nm | 3.58 E−3 |
| 1,450 nm | 1.39 E−2 |

Referring to Table 3, the longer absorption peak wavelength of the quantum dots, the higher N-type mobility. This result may demonstrate, e.g., that the larger particle size of the quantum dots, that is, the longer absorption peak wavelength thereof and thus better charge mobility.

### Experimental Example 2: Manufacturing and Evaluation of Photodiode

After depositing MoO₃ on an indium tin oxide (ITO) substrate, a dispersion of the quantum dot according to Example 5 is spin-coated thereon to form a semiconductor layer. On the formed semiconductor layer, TiO₂ as an electron transport layer (ETL) material is spin-coated, and aluminum is deposited thereon to form an electrode (contact).

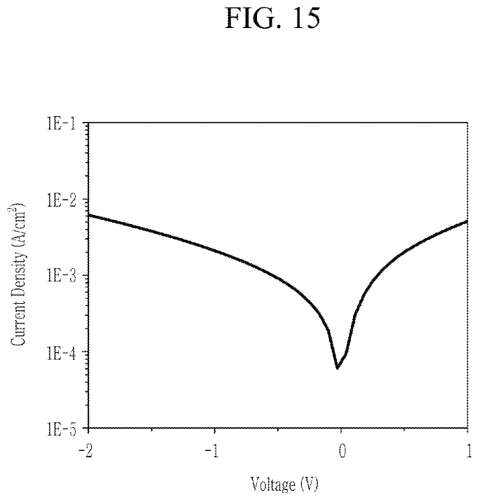

The manufactured diode is measured with respect to current density when a voltage is applied thereto in a dark room where no light passes through, and the results are shown in FIG. 15. Referring to FIG. 15, when the diode is irradiated with Vis-IR light, the semiconductor layer including the quantum dot of Example 5 absorbs light and converts the light to electrical signals, improving the current density.

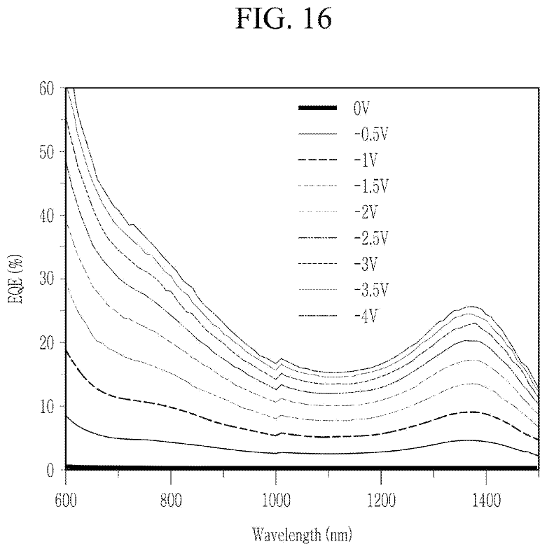

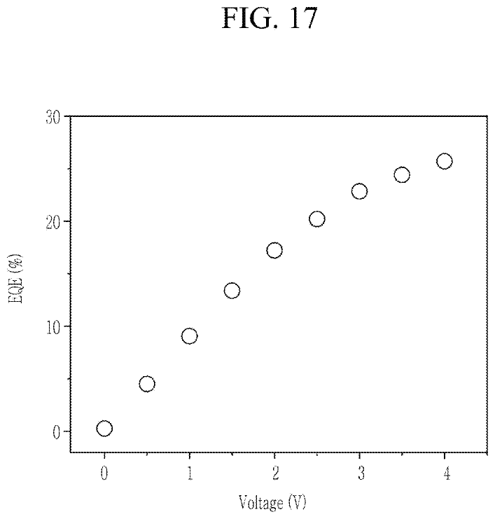

In addition, the manufactured diode is measured with respect to external quantum efficiency (EQE), and the results are shown in FIGS. 16 and 17.

FIG. 16 is a diagram showing the EQE measurement result in the Vis-IR region, while gradually increasing a voltage applied to the diode. Referring to FIG. 16, the higher voltage applied to the diode, the higher EQE of the diode, and for example, the higher voltage, the higher EQE at about 1,300 nm of the absorption peak wavelength range of the quantum dot included in the diode.

FIG. 17 is a graph showing the EQE increase pattern to the applied voltage. Referring to FIG. 17, the diode exhibits EQE of greater than 20% at a voltage of about 3 volts (V), and even though the voltage is increased to 4 V, the diode is not damaged and exhibits increased EQE to greater than 25%, but the increase slows down, gradually approaching saturation.

In conclusion, a diode including the surface-modified quantum dot according to an embodiment exhibits excellent electric characteristics such as, for example, excellent EQE and charge mobility.

### Experimental Example 3: Manufacturing and Evaluation of Photodiode

A photodiode is manufactured similarly to Experimental Example 2 but unlike Experimental Example 2, manufactured as an inverted diode.

After spin-coating ZnO as an electron transport layer (ETL) on an ITO substrate, a semiconductor layer is formed on ZnO by spin-coating a dispersion of InAs quantum dot surface-modified with MPD having an absorption peak wavelength of 1,250 nm, which is similar to the quantum dot of Example 5 but has a smaller particle size than that of the quantum dot of Example 5. After depositing MoO₃ as a hole transport layer (HTL) material on the formed semiconductor layer, silver (Ag) is deposited thereon to form an electrode (contact).

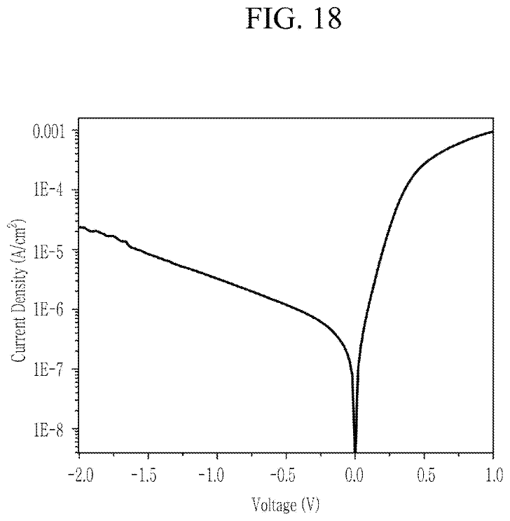

The manufactured diode is measured with respect to current density by applying a voltage thereto in the dark room where no light passes through, and the result is shown in FIG. 18. Referring to FIG. 18, when the diode is irradiated with Vis-IR light, the semiconductor layer including the quantum dot absorbs light and converts the light to electrical signals, improving the current density.

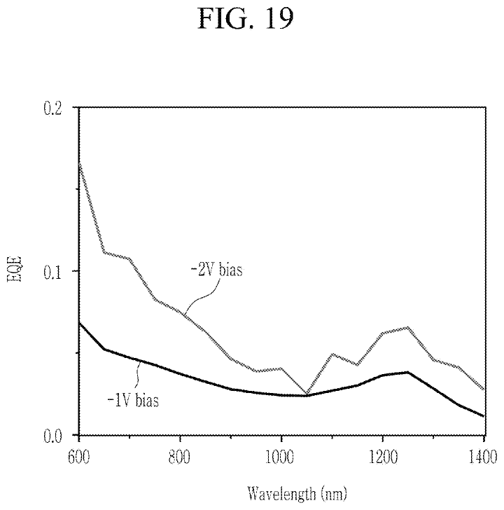

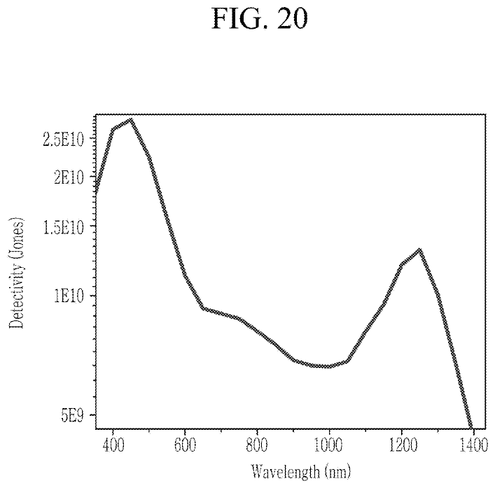

As a result of measuring EQE of the manufactured diode, as shown in FIG. 19, when a bias voltage of −1 V is applied, the diode exhibits very low EQE. As shown in FIG. 20, when the diode is measured with respect to detectivity (Jones, centimeters-hertz^{1/2} per watt (cm·Hz^{1/2}·W⁻¹)) in the Vis-IR region, the detectivity is high at about 1,250 nm. The detectivity, which is defined as a reciprocal of noise-equivalent power, is an indicator of quantifying capability of detecting weak signals. The detectivity is a method of expressing a signal-to-noise ratio, that is, detection capability of the diode, which is proportional to EQE or responsivity of the diode corresponding to a signal size but inversely proportional to a noise current (dark current). As a result of introducing the p-type InAs quantum dot between the semiconductor layer and the hole transport layer (HTL) (MoOx) of the diode, as shown in FIG. 19, when a bias voltage of −2 V is applied, much higher EQE is obtained at about 1,200 nm.

In conclusion, the inverted type photodiode including the quantum dot according to an embodiment in the semiconductor layer exhibits much improved EQE by adding the p-type InAs quantum dot layer between the semiconductor layer and the hole transport layer (HTL).

While this invention has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A method of preparing a quantum dot, comprising:
preparing a precursor solution of a Group IIIA element comprising a precursor of a Group IIIA element, a first amine compound, and a phosphine compound, and heating the precursor solution to maintain the precursor solution at a first temperature;
preparing a precursor solution of a Group VA element comprising a precursor of a Group VA element and a second amine compound;
injecting the precursor solution of the Group VA element into the precursor solution of the Group IIIA element maintained at the first temperature to form a mixture and to react the precursor solution of the Group VA element and the precursor solution of the Group IIIA element; and
increasing temperature of the mixture to a second temperature that is higher than the first temperature to cause an additional reaction,
wherein the prepared quantum dot has an absorption peak wavelength of greater than or equal to about 1,100 nanometers and less than or equal to about 1,600 nanometers in a visible-infrared absorption spectrum.

2. The method of claim 1, wherein:
the precursor of the Group IIIA element comprises a halide of the Group IIIA element, a sulfide of the Group IIIA element, an amine compound of the Group IIIA element, or a combination thereof; and
the precursor of the Group VA element comprises a halide of the Group VA element, a sulfide of the Group VA element, an amine compound of the Group VA element, or a combination thereof.

3. The method of claim 1, wherein the first amine compound and the second amine compound are the same or different and are each independently RNH₂, R₂NH, or a combination thereof, wherein, each R independently represents a C5 to C40 substituted or unsubstituted aliphatic hydrocarbon group, a C6 to C40 substituted or unsubstituted aromatic hydrocarbon group, or a combination thereof.

4. The method of claim 1, wherein the phosphine compound comprises R₃PO, R₂HPO, RH₂PO, R₃P, R₂PH, RPH₂, RPO(OH)₂, RHPOOH, RHPOOH, R₂POOH, or a combination thereof, wherein, each R independently represents a C5 to C40 substituted or unsubstituted aliphatic hydrocarbon group, a C6 to C40 substituted or unsubstituted aromatic hydrocarbon group, or a combination thereof.

5. The method of claim 1, wherein the first temperature is greater than or equal to about 220 °C and less than or equal to about 270 °C, and the second temperature is greater than about 270 °C and less than or equal to about 380 °C.

6. The method of claim 1, wherein a temperature increase from the first temperature to the second temperature occurs within 5 minutes.

7. The method of claim 1, wherein after the additional reaction at the second temperature, the method further comprises replacing the first amine compound, the second amine compound, the phosphine compound, or a combination thereof on a surface of the quantum dot obtained therefrom with an aliphatic hydrocarbon compound substituted with a hydroxyl group and a thiol group, a metal halide, or a combination thereof.

8. The method of claim 7, wherein the aliphatic hydrocarbon compound substituted with the hydroxyl group and the thiol group comprises 1-hydroxy-2-mercaptoethane, 1,2-dihydroxy-3-mercaptopropane, or a combination thereof, and the metal halide comprises InBr, InI, InCl, ZnCl₂, ZnI₂, ZnBr₂, or a combination thereof.

9. A quantum dot, comprising:
a Group IIIA element, and
a Group VA element,
wherein the quantum dot
does not comprise mercury, cadmium, lead, or a combination thereof, and
has an absorption peak wavelength of greater than or equal to about 1,100 nanometers and less than or equal to about 1,600 nanometers in a visible-infrared absorption spectrum.

10. The quantum dot of claim 9, wherein:
the Group IIIA element comprises indium, aluminum, gallium, or a combination thereof, and
the Group VA element comprises arsenic, antimony, bismuth, or a combination thereof.

11. The quantum dot of claim 9, wherein the quantum dot comprises indium and arsenic.

12. The quantum dot of claim 9, wherein the quantum dot comprises an amine compound, a phosphine compound, or a combination thereof on a surface thereof.

13. The quantum dot of claim 9, wherein the quantum dot comprises a ligand derived from an aliphatic hydrocarbon compound substituted with a hydroxyl group and a thiol group, a metal halide, or a combination thereof on a surface thereof.

14. The quantum dot of claim 13, wherein the ligand is derived from a linear or branched aliphatic hydrocarbon compound having 2 to 30 carbon atoms substituted with a hydroxyl group and a thiol group.

15. The quantum dot of claim 13, wherein the metal halide comprises a halide of a Group IIIA metal, a halide of a Group IIA metal, or a combination thereof.

16. An electronic device, comprising a first electrode and a second electrode spaced apart from each other, and
a semiconductor layer between the first electrode and the second electrode,
wherein the semiconductor layer comprises a quantum dot, and
wherein the quantum dot
comprises a Group IIIA element and a Group VA element of the periodic table of elements,
does not comprise mercury, cadmium, lead, or a combination thereof, and
has an absorption peak wavelength of greater than or equal to about 1,100 nanometers and less than or equal to about 1,600 nanometers in a visible-infrared absorption spectrum.

17. The electronic device of claim 16,
wherein the quantum dot comprises indium and arsenic.

18. The electronic device of claim 16, wherein the first electrode and the second electrode have main surfaces facing each other, and the semiconductor layer is interposed between the first electrode and the second electrode.

19. The electronic device of claim 16, wherein the electronic device further comprises:
a charge auxiliary layer between the semiconductor layer and the first electrode, between the semiconductor layer and the second electrode, or both;
a third electrode facing the semiconductor layer and an insulating layer interposed between the semiconductor layer and the third electrode; or
a combination thereof.

20. The quantum dot of claim 9,
wherein the quantum dot
has an average particle size of greater than or equal to about 2.5 nanometers and less than or equal to about 20 nanometers, or
has a molar ratio of the Group IIIA element to the Group VA element of about 1:1 to about 2:1.
